(19) United States
(12) Patent Application Publication
(10) Pub. No.: US 2025/0063928 A1
(43) Pub. Date: Feb. 20, 2025

(54) DISPLAY PANEL AND METHOD OF MANUFACTURING THE SAME

(71) Applicant: Samsung Display Co., Ltd., Yongin-si (KR)

(72) Inventors: SANGYUN LIM, Yongin-si (KR); JEWON YOO, Yongin-si (KR); HYUN-JOO HWANG, Yongin-si (KR)

(21) Appl. No.: 18/791,718

(22) Filed: Aug. 1, 2024

(30) Foreign Application Priority Data
Aug. 18, 2023 (KR) 10-2023-0108112

(51) Int. Cl. H10K 59/88; H01L 27/12; H10K 59/121; H10K 59/126; H10K 59/131; H10K 59/35

(52) U.S. Cl. CPC H10K 59/88; H10K 59/1213; H10K 59/126; H10K 59/131; H10K 59/351; H10K 59/352; H10K 59/353; H01L 27/124

(57) ABSTRACT

A display panel includes a base layer including a first area including a display area and a transmission area and a second area around at least a portion of the first area and having a light transmittance lower than the first area, and first pixels, each of the first pixels including sub-pixels in the display area; and a dummy electrode in the display area. Each of the sub-pixels of the first pixel includes a pixel circuit including first transistors and a light emitting element connected to the first transistors, each of the first transistors includes a semiconductor pattern unit and a gate electrode overlapping the semiconductor pattern unit, and the dummy electrode is spaced from the semiconductor pattern unit in a plan view.

### CROSS-REFERENCE TO RELATED APPLICATION

The present application claims priority to and the benefit of Korean Patent Application No. 10-2023-0108112, filed on Aug. 18, 2023, in the Korean Intellectual Property Office, the entire disclosure of which is incorporated by reference herein.

### BACKGROUND

### 1. Field

The present disclosure relates to a display panel with improved reliability and a method of manufacturing the display panel.

### 2. Description of the Related Art

When a light is incident to an active area of a transistor of a display panel, the transistor is deteriorated due to the light.

### SUMMARY

The present disclosure provides a display panel including a transistor with improved reliability.

The present disclosure provides a method of manufacturing the display panel including the transistor with improved reliability.

Embodiments of the present disclosure provide a display panel including a base layer including a first area including a display area and a transmission area and a second area around at least a portion of the first area and having a light transmittance lower than the first area and first pixels, each of the first pixels including sub-pixels located in the display area and a dummy electrode in the display area. Each of the sub-pixels in the first pixels includes a pixel circuit including first transistors and a light emitting element connected to the first transistors.

Each of the first transistors includes a semiconductor pattern unit and a gate electrode overlapping the semiconductor pattern unit.

The dummy electrode is spaced from the semiconductor pattern unit in a plan view.

The display panel further includes a first insulating layer on which the gate electrode and the dummy electrode are located, the first insulating layer located on the base layer, a second insulating layer on the first insulating layer and covering the gate electrode and the dummy electrode, and a third insulating layer on the second insulating layer and covering the second insulating layer.

The second insulating layer has a refractive index greater than a refractive index of the first insulating layer and a refractive index of the third insulating layer.

The second insulating layer includes silicon nitride (SiNx), and each of the first insulating layer and the third insulating layer includes silicon oxide (SiOx).

The dummy electrode extends in one direction and has a continuous shape in a plan view.

The dummy electrode includes a plurality of sub-dummy electrodes, the sub-dummy electrodes are spaced from each other, and the sub-dummy electrodes at least partially overlap each other when viewed in a direction from the transmission area to the pixel circuit.

The dummy electrode includes a first portion extending in a first direction and overlapping at least one semiconductor pattern when viewed in a second direction from the transmission area to the display area and second portions extending in the second direction and respectively connected to both ends of the first portion.

The display panel further includes a light blocking layer on the base layer, and the light blocking layer overlaps the display area and does not overlap the transmission area, and the dummy electrode overlaps the light blocking layer.

The display panel further includes a plurality of light blocking layers on the base layer and light blocking layer connection lines located between two light blocking layers of the plurality of light blocking layers and connecting the two light blocking layers to each other.

The display area includes a plurality of display areas, the first area further includes a line area located between the display areas, and the transmission area is around the display area and the line area.

The dummy electrode and the gate electrode include the same material.

The display panel further includes second pixels, each of the second pixels including sub-pixels and located in the second area, each of the sub-pixels in the second pixels includes a pixel circuit including second transistors and a light emitting element connected to the second transistors, and the sub-pixels in the first pixels are greater than the sub-pixels included in the second pixels, and configured to emit the same light as the sub-pixels in the first pixels.

Each of the first pixels includes one first sub-pixel configured to emit a first color light, one second sub-pixel configured to emit a second color light, and two third sub-pixels configured to emit a third color light, the first sub-pixel is spaced from the second sub-pixel in one direction, one third sub-pixel of the two third sub-pixels is spaced from an other third sub-pixel of the two third sub-pixels, the first sub-pixel is spaced from the one third sub-pixel in a first diagonal direction, the second sub-pixel is spaced apart from the one third sub-pixel in a second diagonal direction, and a light emitting area of each of the first, second, and third sub-pixels increases in an order of the third sub-pixels, the second sub-pixel, and the first sub-pixel.

A density of the first pixels in the first area is less than a density of second pixels in the second area.

The dummy electrode overlaps at least two semiconductor pattern units when viewed in a direction from the transmission area to the pixel circuit.

The display panel further includes an electronic module overlapping the first area and located under the display panel, and the electronic module includes at least one of a light emitting module and a light receiving module.

Embodiments of the present disclosure provide a display panel including a base layer including a first area including a display area and a transmission area and a second area around at least a portion of the first area and having a light transmittance lower than the first area, first pixels, each of the first pixels including sub-pixels located in the display area and a dummy electrode in the display area.

Each of the sub-pixels includes a pixel circuit including first transistors and a light emitting element connected to the first transistors. Each of the first transistors includes a semiconductor pattern unit and a gate electrode overlapping the semiconductor pattern unit. At least a portion of the semiconductor pattern unit is blocked by the dummy electrode when viewed in a direction from the transmission area to the pixel circuit.

The display panel further includes a first insulating layer on which the gate electrode and the dummy electrode are located, the first insulating layer being on the base layer, a second insulating layer on the first insulating layer and covering the gate electrode and the dummy electrode, and a third insulating layer on the second insulating layer and covering the second insulating layer.

The second insulating layer has a refractive index greater than a refractive index of the first insulating layer and a refractive index of the third insulating layer.

The second insulating layer includes at least one curved portion.

The curved portion overlaps at least a portion of the dummy electrode.

The number of the semiconductor pattern units partially blocked by the dummy electrode is two or more when viewed in the direction from the transmission area to the pixel circuit.

According to the above, as the dummy electrode is provided to the display panel, the transistor is prevented from being photo-degraded. In addition, the dummy electrode is easily formed according to the method of manufacturing the display panel.

### BRIEF DESCRIPTION OF THE DRAWINGS

The above and other aspects and features of embodiments of the present disclosure will become readily apparent by reference to the following detailed description when considered in conjunction with the accompanying drawings wherein:

FIG. 1 is a perspective view of an electronic device according to one or

more embodiments of the present disclosure;

FIG. 2A is an exploded perspective view of an electronic device according to one or more embodiments of the present disclosure;

FIG. 2B is a block diagram of an electronic device according to one or more embodiments of the present disclosure;

FIG. 3 is an equivalent circuit diagram of a pixel according to one or more embodiments of the present disclosure;

FIG. 4 is a plan view of an active area according to one or more embodiments of the present disclosure;

FIG. 5 is a plan view of a portion of a display area and a portion of a line area according to one or more embodiments of the present disclosure;

FIG. 6 is a cross-sectional view taken along the line I-I′ of FIG. 4;

FIG. 7 is a cross-sectional view taken along the line II-II′ of FIG. 4;

FIG. 8A is a cross-sectional view of a display panel according to a comparative example;

FIG. 8B is a cross-sectional view of a display panel according to one or more embodiments of the present disclosure;

FIG. 9 is a plan view of a semiconductor pattern according to one or more embodiments of the present disclosure;

FIG. 10 is a plan view illustrating an overlapping relationship between a semiconductor pattern and a conductive layer according to one or more embodiments of the present disclosure;

FIGS. 11A, 11B, and 11C are plan views respectively illustrating a semiconductor pattern, a conductive layer, and a stack structure of the semiconductor pattern and the conductive layer according to one or more embodiments of the present disclosure;

FIG. 12A is a plan view of a display module according to one or more embodiments of the present disclosure;

FIG. 12B is a plan view of a display module according to one or more embodiments of the present disclosure; and

FIG. 12C is a plan view of a display module according to one or more embodiments of the present disclosure.

### DETAILED DESCRIPTION

The present disclosure may be variously modified and realized in many different forms, and thus specific embodiments will be exemplified in the drawings and described in detail hereinbelow. However, the present disclosure should not be limited to the specific disclosed forms, and may be construed to include all modifications, equivalents, and/or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like reference numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in the present disclosure, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “and/or” includes any and all combinations of one or more of the associated listed items. Throughout the present disclosure, the expression “at least one of a, b, or c” indicates only a, only b, only c, both a and b, both a and c, both b and c, all of a, b, and c, or variations thereof.

Hereinafter, one or more embodiments of the present disclosure will be described with reference to accompanying drawings.

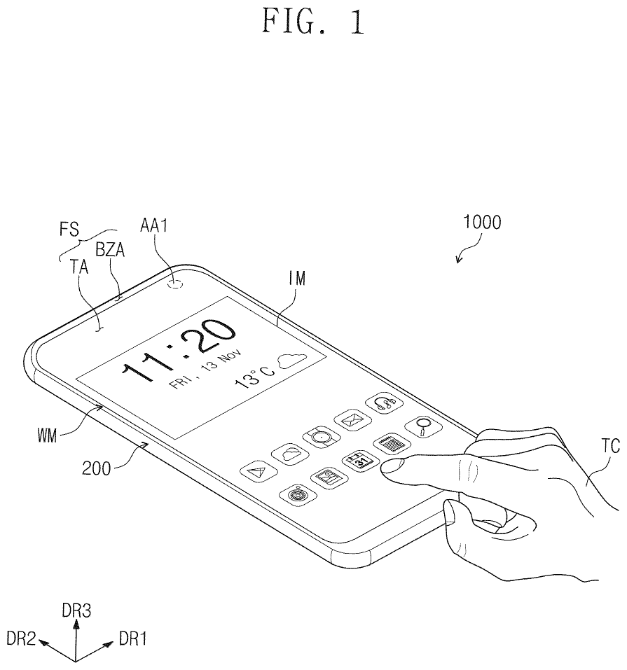

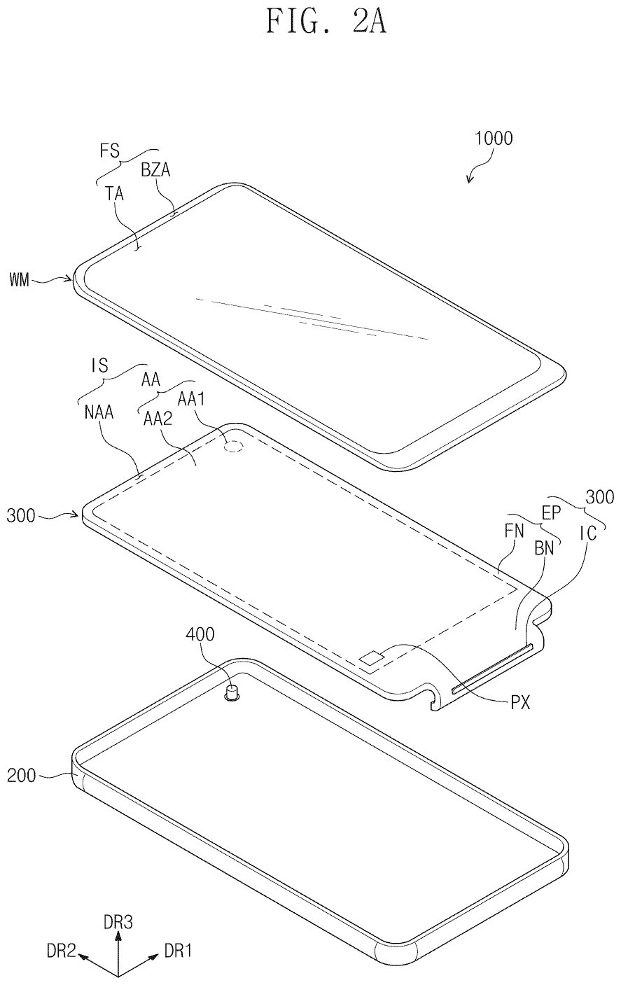

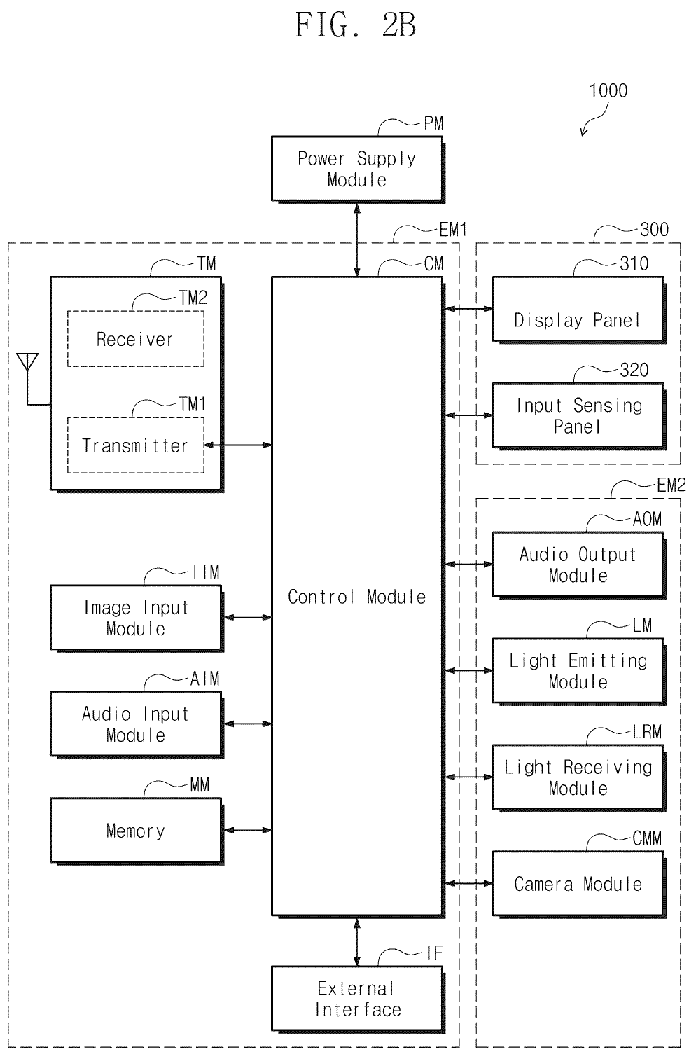

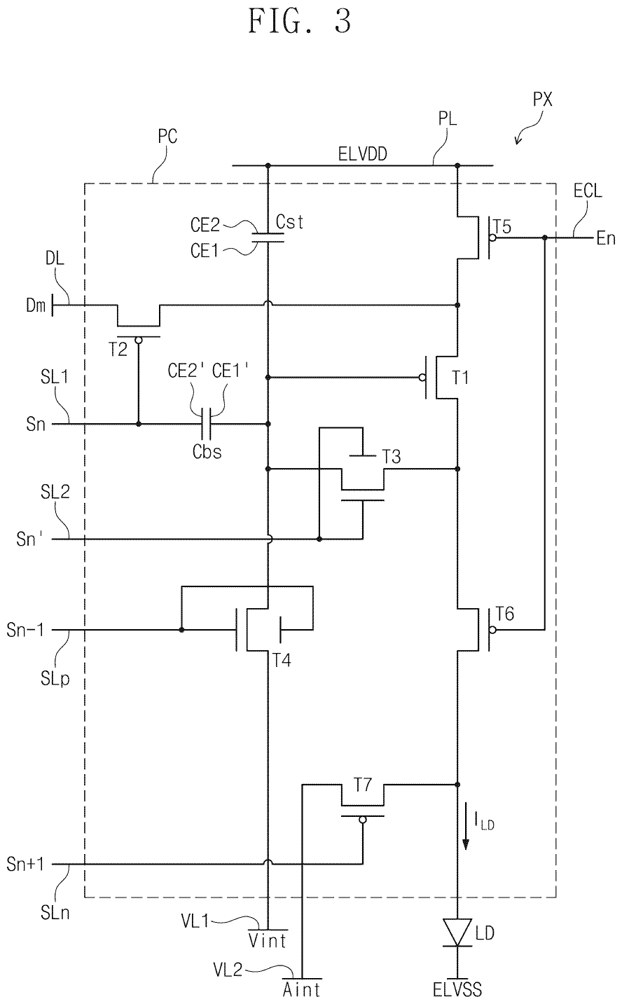

FIG. 1 is a perspective view of an electronic device 1000 according to one or more embodiments of the present disclosure. FIG. 2A is an exploded perspective view of the electronic device 1000 according to one or more embodiments of the present disclosure. FIG. 2B is a block diagram of the electronic device 1000 according to one or more embodiments of the present disclosure. FIG. 3 is an equivalent circuit diagram of a pixel PX according to one or more embodiments of the present disclosure.

The electronic device 1000 may be a device activated in response to an electrical signal. The electronic device 1000 may include various embodiments. For example, the electronic device 1000 may include a tablet computer, a notebook computer, a computer, a smart television, or the like. In the present embodiment, a smartphone will be described as a representative example of the electronic device 1000.

The electronic device 1000 may display an image IM through a display surface IS, which is substantially parallel to each of a first direction DR1 and a second direction DR2, toward a third direction DR3. The display surface IS, through which the image IM is displayed, may correspond to a front surface of the electronic device 1000 and a front surface FS of a window WM.

Hereinafter, the display surface and the front surface of the electronic device 1000 and the front surface of the window WM will be assigned with the same reference numeral. The image IM may include a still image as well as a video. FIG. 1 shows a clock widget and application icons as a representative example of the image IM.

In the present embodiment, front (or upper) and rear (or lower) surfaces of each member of the electronic device 1000 may be defined with respect to a direction in which the image IM is displayed (e.g., the third direction DR3). The front and rear surfaces may be opposite to each other in the third direction DR3, and a normal line direction of each of the front and rear surfaces may be substantially parallel to the third direction DR3. A separation distance between the front and rear surfaces may correspond to a thickness of the electronic device 1000 in the third direction DR3.

According to one or more embodiments, the electronic device 1000 may sense an external input TC applied thereto from the outside. The external input TC may include various types of external inputs, such as a part of the user's body, light, heat, or pressure. In the present embodiment, the external input TC is shown as a hand of the user applied to the front surface FS of the electronic device 1000. However, this is merely one example, and the external input TC may be provided in various ways. In addition, the electronic device 1000 may sense the external input TC applied to a side or rear surface of the electronic device 1000 depending on its structure, and it should not be limited to a specific embodiment.

In the present embodiment, the electronic device 1000 may include a first area AA1 defined in a transmission area TA. The first area AA1 may be an area of a display module 300, which is described later, overlapping an electronic module 400. FIG. 2A shows a circular shape defined in a right upper end portion as the first area AA1, however, the present disclosure should not be limited thereto or thereby. Depending on the number and shape of the electronic modules 400, the first area AA1 may be provided in various numbers and shapes in the display module 300, however, the present disclosure should not be particularly limited.

The electronic device 1000 may receive external signals required for the electronic module 400 via the first area AA1 or may provide signals output from the electronic module 400 to the outside via the first area AA1. According to one or more embodiments of the present disclosure, as the first area AA1 is defined in the transmission area TA, a size of a bezel area BZA defining the transmission area TA may be reduced.

Referring to FIG. 2A, the electronic device 1000 may include the window WM, a housing 200, the display module 300, and the electronic module 400. The window WM and the housing 200 may be coupled to each other to provide an exterior of the electronic device 1000.

The window WM may include an insulating panel. For example, the window WM may include a glass material, a plastic material, or a combination thereof.

The front surface FS of the window WM may define the front surface FS of the electronic device 1000 as described above. The transmission area TA may be an optically transparent area. For example, the transmission area TA may be an area having a visible light transmittance of about 90% or more.

The bezel area BZA may be an area having a relatively lower transmittance as compared with the transmission area TA. The bezel area BZA may define a shape of the transmission area TA. The bezel area BZA may be adjacent to the transmission area TA and may be around (e.g., may surround) the transmission area TA.

The bezel area BZA may have a desired color (e.g., a predetermined color). The bezel area BZA may be defined by a bezel layer provided separately from a transparent substrate defining the transmission area TA or may be defined by an ink layer formed by being inserted into or by printing a color on the transparent substrate.

The display module 300 may include a display panel EP and a driving circuit IC.

The display panel EP may display the image IM and may sense the external input TC. The display panel EP may include a front surface IS in which an active area AA and a peripheral area NAA are defined. The active area AA may be an area activated in response to an electrical signal. In the present embodiment, the active area AA may be an area where the image IM is displayed and the external input TC is sensed. The active area AA may be an area in which a plurality of pixels PX is arranged.

The active area AA may overlap at least a portion of the transmission area Ta in the third direction DR3. As an example, the transmission area TA may overlap all or at least a portion of the active area AA. Accordingly, a user may view the image IM or may provide the external input TC via the transmission area TA, however, this is merely an example. That is, an area through which the image IM is displayed and an area through which the external input TC is sensed may be separated from each other in the active area AA, and they should not be limited to a particular embodiment.

The peripheral area NAA may be covered by the bezel area BZA. The peripheral area NAA may be disposed adjacent to the active area AA along an edge or a periphery of the active area AA. The peripheral area NAA may be around (e.g., may surround) the active area AA. The peripheral area NAA may be an area through which the image IM is not displayed. A driving circuit or a driving line may be disposed in the peripheral area NAA to drive the active area AA.

In the present embodiment, the display panel EP is assembled in a flat state with the active area AA and peripheral area NAA facing the window WM. However, this is merely an example, a portion of the peripheral area NAA of the display panel EP may be bent. As an example, the portion of the peripheral area NAA may be disposed on a rear surface of the electronic device 1000, and thus, the bezel area BZA viewed from the front surface FS of the electronic device 1000 may decrease. According to one or more embodiments, the display panel EP may be assembled in a state in which a portion of the active area AA is bent. The peripheral area NAA may be omitted from the display panel EP.

The active area AA may include the first area AA1 and a second area AA2. In the present disclosure, the first area AA1 may have a relatively high light transmittance compared with the second area AA2. The first area AA1 may be defined as an area overlapping an area where the electronic module 400 of the display module 300 is disposed in the housing 200. In the present embodiment, the first area AA1 may have a circular shape, however, the first area AA1 may have various shapes such as a polygonal shape, an oval shape, a shape including at least a curved line, however, it should not be particularly limited.

The second area AA2 may be defined adjacent to the first area AA1. The second area AA2 may be around (e.g., may surround) at least a portion of the first area AA1. In the present embodiment, the second area AA2 may entirely surround the first area AA1, however, this is merely an example. According to one or more embodiments, the second area AA2 may be defined to be adjacent to only a portion of an edge of the first area AA1 and should not be particularly limited.

Referring to FIG. 2B, the display module 300 may include a display panel 310 and an input sensor 320. The display panel 310 may generate the image IM. The image IM generated by the display panel 310 may be displayed on the display surface IS and may be visible to the user through the transmission area TA from the outside.

The input sensor 320 may sense the external input TC applied thereto from the outside. As described above, the input sensor 320 may sense the external input TC applied to the window WM.

Referring to FIG. 2A again, the display panel EP may include a flat portion FN and a bending portion BN. The flat portion FN may be assembled to be substantially parallel to a plane defined by the first direction DR1 and the second direction DR2. The active area AA may be defined in the flat portion FN.

The bending portion BN may extend from the flat portion FN and may be bent. The bending portion BN may be assembled to be bent from the flat portion FN and disposed on a rear side of the flat portion FN. Because the bending portion BN overlaps the flat portion FN in a plane when being assembled, the bezel area BZA of the electronic device 1000 may decrease. This is merely an example, and the bending portion BN may be omitted from the display panel EP.

The driving circuit IC may be mounted on the bending portion BN. The driving circuit IC may be provided in a chip form, however, it should not be limited thereto or thereby. According to one or more embodiments, the driving circuit IC may be electrically connected to the display panel EP via a flexible film after being provided to a separate circuit board.

The driving circuit IC may be electrically connected to the active area AA and may apply electrical signals to the active area AA. As an example, the driving circuit IC may include a data driving circuit and may apply data signals to the pixels arranged in the active area AA. According to one or more embodiments, the driving circuit IC may include a touch driving circuit and may be electrically connected to the input sensor disposed in the active area AA. This is merely an example, and according to one or more embodiments, the driving circuit IC may be designed to include a variety of circuits in addition to the above-mentioned circuits or to apply a variety of electrical signals to the active area AA, and it should not be particularly limited.

In one or more embodiments, the electronic device 1000 may further include a main circuit board electrically connected to the display panel EP and the driving circuit IC. The main circuit board may include various driving circuits to drive the display panel EP or a connector to provide a power. The main circuit board may be a rigid printed circuit board (PCB), however, according to one or more embodiments, the main circuit board may be a flexible circuit board, and it should not be particularly limited.

The electronic module 400 may be disposed under the display module 300. The electronic module 400 may receive the external input via the first area AA1 or may output signals via the first area AA1. According to one or more embodiments of the present disclosure, as the first area AA1 having a relatively high transmittance is defined in the active area AA, the electronic module 400 may be disposed to overlap the active area AA in the third direction DR3. Accordingly, the increase in size of the bezel area BZA may be prevented.

Referring to FIG. 2B, the electronic device 1000 may include the display module 300, a power supply module PM, a first electronic module EM1, and a second electronic module EM2. The display module 300, the power supply module PM, the first electronic module EM1, and the second electronic module EM2 may be electrically connected to each other. FIG. 2B shows the display panel 310 and the input sensor 320 from among the components of the display module 300.

The power supply module PM may supply a power required for the overall operation of the electronic device 1000. The power supply module PM may include a conventional battery module.

The first electronic module EM1 and the second electronic module EM2 may include various functional modules to operate the electronic device 1000. The first electronic module EM1 may be mounted directly on a mother board that is electrically connected to the display panel EP or may be electrically connected to the mother board via a connector after being mounted on a separate substrate.

The first electronic module EM1 may include a control module CM, a wireless communication module TM, an image input module IIM, an audio input module AIM, a memory MM, and an external interface IF. Some modules from among the modules may be electrically connected to the mother board through a flexible circuit board without being mounted on the mother board.

The control module CM may control an overall operation of the electronic device 1000. The control module CM may be, but not limited to, a microprocessor. For example, the control module CM may activate or deactivate the display module 300. The control module CM may control other modules, such as the image input module IIM, the audio input module AIM, or the like, based on a touch signal provided from the display panel EP.

The wireless communication module TM may transmit and/or receive a wireless signal to/from other terminals using a Bluetooth or WiFi link. The wireless communication module TM may transmit and/or receive a voice signal using a general communication line. The wireless communication module TM may include a transmitter TM1 that modulates a signal to be transmitted and transmits the modulated signal and a receiver TM2 that demodulates the signal applied thereto.

The image input module IIM may process an image signal and may convert the image signal into image data that may be displayed through the display panel EP. The audio input module AIM may receive an external sound signal through a microphone in a record mode or a voice recognition mode and may convert the external sound signal to electrical voice data.

The external interface IF may serve as an interface between the control module CM and external devices, such as an external charger, a wired/wireless data port, a card socket e.g., a memory card and a SIM/UIM card, etc.

The second electronic module EM2 may include an audio output module AOM, a light emitting module LM, a light receiving module LRM, and a camera module CMM. The components may be electrically connected to the display panel EP after being directly mounted on the mother board, may be electrically connected to the display panel EP via a connector after being mounted on a separate substrate, or may be electrically connected to the first electronic module EM1.

The audio output module AOM may convert the sound data provided from the wireless communication module TM or the sound data stored in the memory MM and may output the converted sound data to the outside.

The light emitting module LM may generate a light and may output the light. The light emitting module LM may emit an infrared ray. The light emitting module LM may include an LED element. The light receiving module LRM may sense the infrared ray. The light receiving module LRM may be activated when the infrared ray having a suitable level (e.g., a predetermined level) or higher is sensed. The light receiving module LRM may include a complementary metal oxide semiconductor (CMOS) sensor. The infrared ray generated by and output from the light emitting module LM may be reflected by an external object, e.g., a user's finger or face, and the reflected infrared ray may be incident into the light receiving module LRM. The camera module CMM may take an image of an external object.

According to one or more embodiments, the electronic module 400 may include at least one of the components of the second electronic module EM2. For example, the electronic module 400 may include at least one of a camera, a speaker, a light sensing sensor, and/or a heat sensing sensor. The electronic module 400 may sense the external object via the first area AA1 or may provide a sound signal, such as a voice, to the outside through the first area AA1. In addition, the electronic module 400 may include a plurality of components, and it should not be limited to a particular embodiment. In one or more embodiments, the electronic module 400 may be attached to the display panel EP by a separate adhesive.

Referring to FIG. 2A again, the housing 200 may be coupled with the window WM. The housing 200 may be coupled with the window WM to provide a suitable inner space (e.g., a predetermined inner space) and may define the exterior of the electronic device 1000. The display module 300 and the electronic module 400 may be accommodated in the inner space.

The housing 200 may include a material with a relatively high rigidity. For example, the housing 200 may include a glass, plastic, and/or metal material or a plurality of frames and/or plates of combinations thereof. The housing 200 may stably protect the components of the electronic device 1000 accommodated in the inner space from external impacts.

FIG. 3 is an equivalent circuit diagram of the pixel PX according to one or more embodiments of the present disclosure.

Hereinafter, one pixel PX will be described in detail with reference to FIG. 3.

The pixel PX may include a light emitting element LD and a pixel circuit PC. The pixel circuit PC may include a plurality of transistors T1 to T7, a storage capacitor Cst, and a boosting capacitor Cbs. The transistors T1 to T7 and the storage capacitor Cst may be electrically connected to signal lines SL1, SL2, SLp, SLn, ECL, and DL, a first initialization voltage line VL1, a second initialization voltage line VL2 (or referred to as an anode initialization voltage line), and a driving voltage line PL. According to one or more embodiments, at least one of the lines, e.g., the driving voltage line PL, may be shared by the pixels PX adjacent to each other.

The transistors T1 to T7 may include a driving transistor T1, a switching transistor T2, a compensation transistor T3, a first initialization transistor T4, an operation control transistor T5, an emission control transistor T6, and a second initialization transistor T7.

The light emitting element LD may include a first electrode, e.g., an anode electrode or a pixel electrode, and a second electrode, e.g., a cathode electrode or a common electrode. The first electrode of the light emitting element LD may be connected to the driving transistor T1 via the emission control transistor T6 to receive a driving current ILD, and the second electrode may receive a low power voltage ELVSS. The light emitting element LD may generate a light having a luminance corresponding to the driving current ILD.

Some transistors of the transistors T1 to T7 may be an n-channel MOSFET (NMOS), and the other transistors of the transistors T1 to T7 may be a p-channel MOSFET (PMOS). As an example, the compensation transistor T3 and the first initialization transistor T4 from among the transistors T1 to T7 may be the n-channel MOSFET (NMOS), and the other transistors from among the transistors T1 to T7 may be the p-channel MOSFET (PMOS).

According to one or more embodiments, from among the transistors T1 to T7, the compensation transistor T3 and the first initialization transistor T4, may be the NMOS, and the other transistors may be the PMOS. According to one or more embodiments, from among the transistors T1 to T7, only one transistor may be the NMOS, and the other transistors may be the PMOS. According to one or more embodiments, all the transistors T1 to T7 may be the NMOS or the PMOS.

The signal lines may include a first scan line SL1 transmitting a first scan signal Sn, a second scan line SL2 transmitting a second scan signal Sn′, a prior scan line SLp transmitting a prior scan signal Sn−1 to the first initialization transistor T4, an emission control line ECL transmitting an emission control signal En to the operation control transistor T5 and the emission control transistor T6, a next scan line SLn transmitting a next scan signal Sn+1 to the second initialization transistor T7, and a data line DL crossing the first scan line SL1 and transmitting a data signal Dm.

The driving voltage line PL may transmit a driving voltage ELVDD to the driving transistor T1, and the first initialization voltage line VL1 may transmit an initialization voltage Vint to initialize the driving transistor T1 and the pixel electrode.

A driving gate electrode of the driving transistor T1 may be connected to the storage capacitor Cst, a driving source area of the driving transistor T1 may be connected to the driving voltage line PL via the operation control transistor T5, and a driving drain area of the driving transistor T1 may be electrically connected to the first electrode of the light emitting element LD via the emission control transistor T6. The driving transistor T1 may receive the data signal Dm in response to a switching operation of the switching transistor T2 and may supply the driving current ILD to the light emitting element LD.

A switching gate electrode of the switching transistor T2 may be connected to the first scan line SL1 transmitting the first scan signal Sn, a switching source area of the switching transistor T2 may be connected to the data line DL, and a switching drain area of the switching transistor T2 may be connected to the driving source area of the driving transistor T1 and may be connected to the driving voltage line PL via the operation control transistor T5. The switching transistor T2 may be turned on in response to the first scan signal Sn provided through the first scan line SL1 and may perform the switching operation to transmit the data signal Dm applied to the data line DL to the driving source area of the driving transistor T1.

A compensation gate electrode of the compensation transistor T3 may be connected to the second scan line SL2. A compensation drain area of the compensation transistor T3 may be connected to the driving drain area of the driving transistor T1 and may be connected to the pixel electrode of the light emitting element LD via the emission control transistor T6. A compensation source area of the compensation transistor T3 may be connected to a first electrode CE1 of the storage capacitor Cst and the driving gate electrode of the driving transistor T1. In addition, the compensation source area of the compensation transistor T3 may be connected to a first initialization drain area of the first initialization transistor T4.

The compensation transistor T3 may be turned on in response to the second scan signal Sn′ applied thereto via the second scan line SL2 and may electrically connect the driving gate electrode and the driving drain area of the driving transistor T1 to allow the driving transistor T1 to be connected in a diode configuration (e.g., the driving transistor T1 may be diode-connected).

A first initialization gate electrode of the first initialization transistor T4 may be connected to the prior scan line SLp. A first initialization source area of the first initialization transistor T4 may be connected to the first initialization voltage line VL1. The first initialization drain area of the first initialization transistor T4 may be connected to the first electrode CE1 of the storage capacitor Cst, the compensation source area of the compensation transistor T3, and the driving gate electrode of the driving transistor T1. The first initialization transistor T4 may be turned on in response to the prior scan signal Sn−1 applied thereto through the prior scan line SLp and may transmit the initialization voltage Vint to the driving gate electrode of the driving transistor T1 to perform an initialization operation that initializes a voltage of the driving gate electrode of the driving transistor T1.

An operation control gate electrode of the operation control transistor T5 may be connected to the emission control line ECL, an operation control source area of the operation control transistor T5 may be connected to the driving voltage line PL, and an operation control drain area of the operation control transistor T5 may be connected to the driving source area of the driving transistor T1 and the switching drain area of the switching transistor T2.

An emission control gate electrode of the emission control transistor T6 may be connected to the emission control line ECL, an emission control source area of the emission control transistor T6 may be connected to the driving drain area of the driving transistor T1 and the compensation drain area of the compensation transistor T3, and an emission control drain area of the emission control transistor T6 may be connected to a second initialization drain area of the second initialization transistor T7 and the pixel electrode of the light emitting element LD.

The operation control transistor T5 and the emission control transistor T6 may be substantially concurrently (e.g., simultaneously) turned on in response to the emission control signal En applied thereto via the emission control line ECL, and the driving voltage ELVDD may be applied to the light emitting element LD to allow the driving current ILD to flow through the light emitting element LD.

A second initialization gate electrode of the second initialization transistor T7 may be connected to the next scan line SLn, the second initialization drain area of the second initialization transistor T7 may be connected to the emission control drain area of the emission control transistor T6 and the pixel electrode of the light emitting element LD, and the second initialization source area of the second initialization transistor T7 may be connected to the second initialization voltage line VL2 to receive an anode initialization voltage Aint. The second initialization transistor T7 may be turned on in response to the next scan signal Sn+1 applied thereto via the next scan line SLn to initialize the pixel electrode of the light emitting element LD.

According to one or more embodiments, the second initialization transistor T7 may be connected to the emission control line ECL and may be driven in response to the emission control signal En. Positions of the source areas and the drain areas may be changed with each other depending on the types, e.g., a p-type or an n-type, of the transistor.

The storage capacitor Cst may include the first electrode CE1 and a second electrode CE2. The first electrode CE1 of the storage capacitor Cst may be connected to the driving gate electrode of the driving transistor T1, and the second electrode CE2 of the storage capacitor Cst may be connected to the driving voltage line PL. The storage capacitor Cst may be charged with electric charges corresponding to a difference between the voltage of the driving gate electrode of the driving transistor T1 and the driving voltage ELVDD.

A boosting capacitor Cbs may include a first electrode CE1′ and a second electrode CE2′. The first electrode CE1′ of the boosting capacitor Cbs may be connected to the first electrode CE1 of the storage capacitor Cst, and the second electrode CE2′ of the boosting capacitor Cbs may receive the first scan signal Sn. The boosting capacitor Cbs may boost the voltage of the driving gate electrode of the driving transistor T1 at a time point at which the provision of the first scan signal Sn is stopped, and thus, a voltage drop of the driving gate electrode may be compensated for.

Detailed operations of each pixel PX according to one or more embodiments are as follows.

When the prior scan signal Sn−1 is provided via the prior scan line SLp during an initialization period, the first initialization transistor T4 may be turned on in response to the prior scan signal Sn−1, and the driving transistor T1 may be initialized by the initialization voltage Vint provided from the first initialization voltage line VL1.

When the first scan signal Sn and the second scan signal Sn′ are provided via the first scan line SL1 and the second scan line SL2 during a data programming period, the switching transistor T2 and the compensation transistor T3 may be turned on in response to the first scan signal Sn and the second scan signal Sn′. In this case, the driving transistor T1 may be connected in a diode configuration (e.g., the driving transistor T1 may be diode-connected) by the turned-on compensation transistor T3 and may be forward biased.

Then, a compensation voltage Dm+Vth (Vth is a negative (−) value) obtained by subtracting a threshold voltage Vth of the driving transistor T1 from the data signal Dm provided from the data line DL may be applied to the driving gate electrode of the driving transistor T1.

The driving voltage ELVDD and the compensation voltage Dm+Vth may be respectively applied to both ends of the storage capacitor Cst, and the storage capacitor Cst may be charged with electric charges corresponding to a difference in voltage between the both ends thereof.

During a light emitting period, the operation control transistor T5 and the emission control transistor T6 may be turned on by the emission control signal En provided from the emission control line ECL. The driving current ILD according to the difference between the voltage of the driving gate electrode of the driving transistor T1 and the driving voltage ELVDD may be generated, and the driving current ILD may be supplied to the light emitting element LD via the emission control transistor T6.

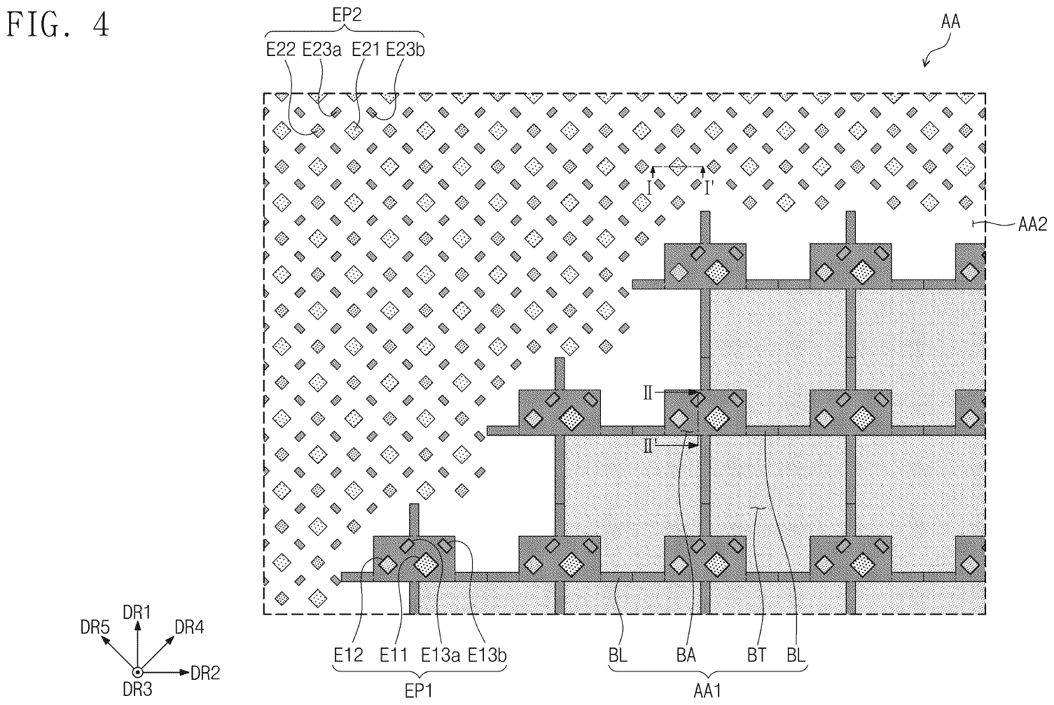

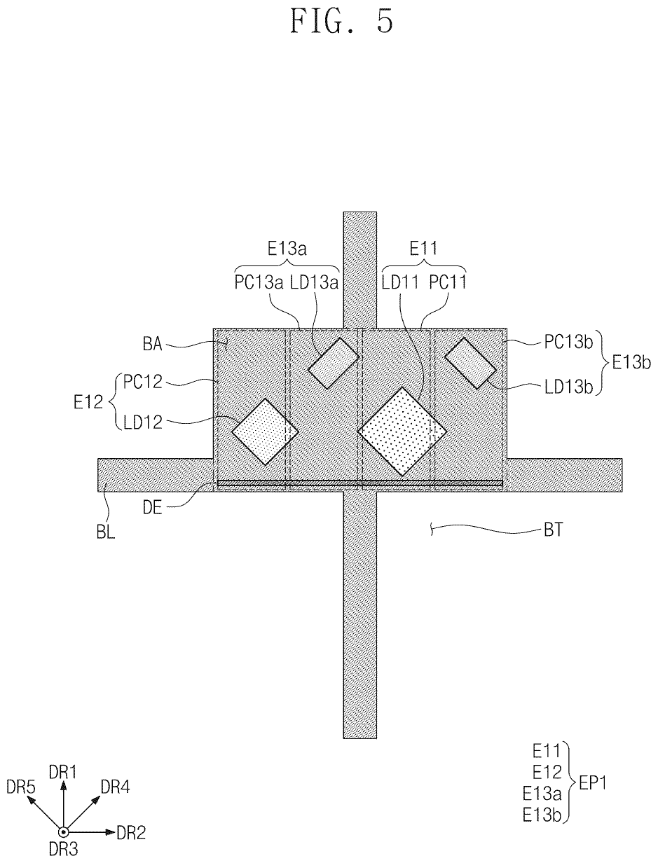

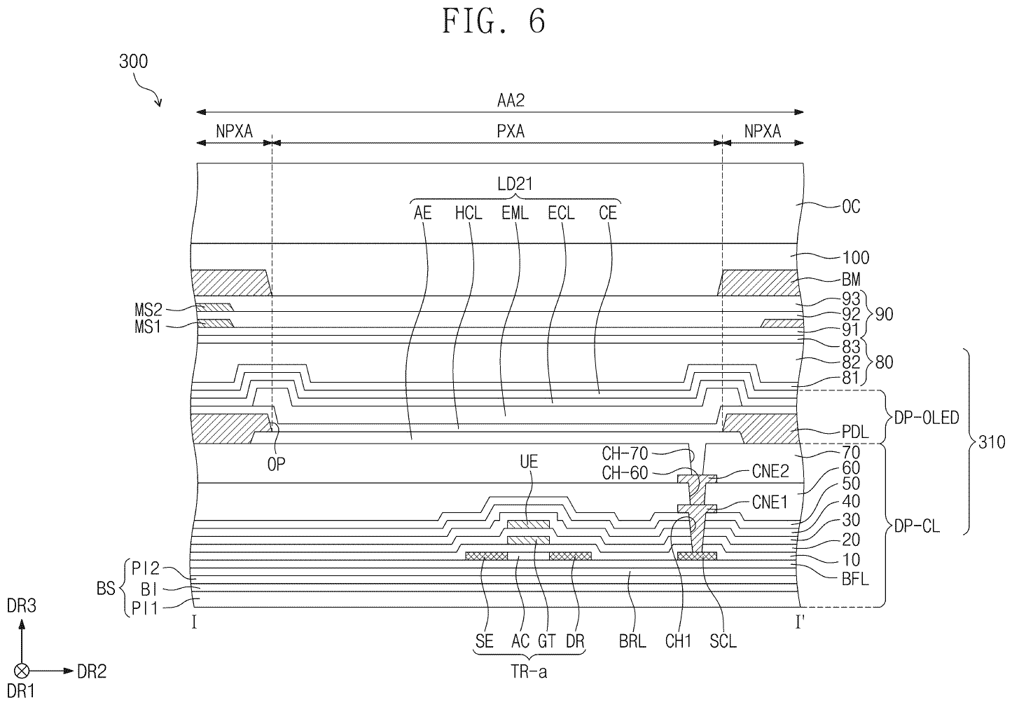

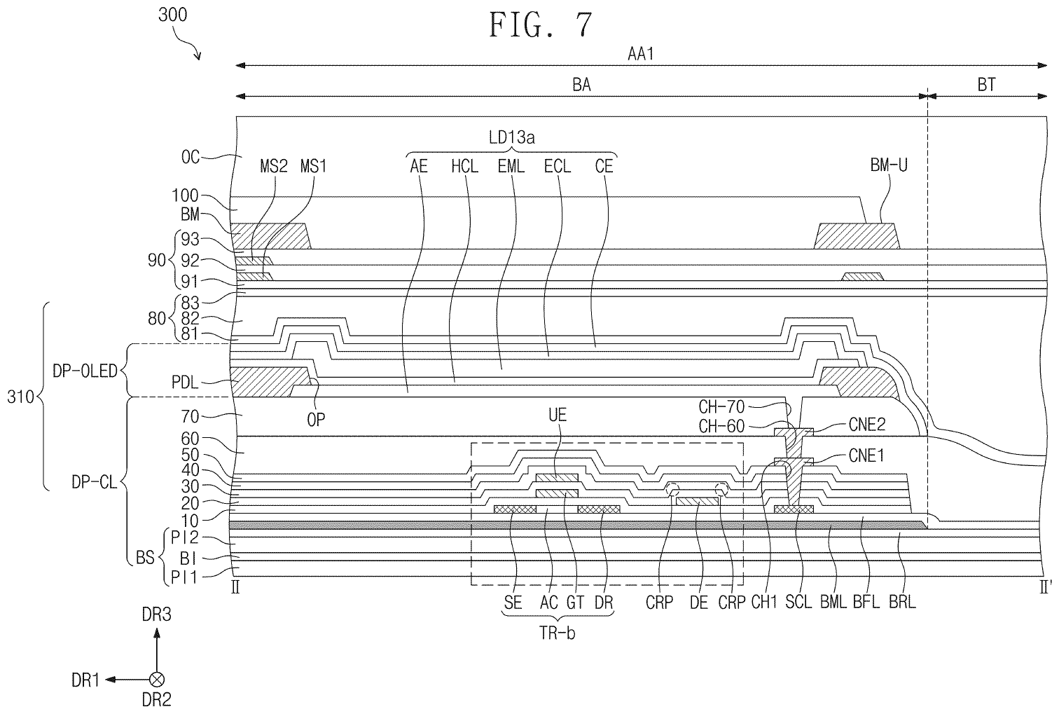

FIG. 4 is a plan view of the active area AA according to one or more embodiments of the present disclosure. FIG. 5 is a plan view of a portion of the display area and a portion of a line area according to one or more embodiments of the present disclosure. FIG. 6 is a cross-sectional view taken along the line I-I′ of FIG. 4. FIG. 7 is a cross-sectional view taken along the line II-II′ of FIG. 4.

Hereinafter, the active area AA is described with reference to FIG. 4.

The active area AA may include the first area AA1 and the second area AA2.

A first pixel EP1 disposed in the first area AA1 and a second pixel EP2 disposed in the second area AA2 may have substantially the same equivalent circuit diagram as that of the pixel PX shown in FIG. 3 with difference only in size.

The second area AA2 may be defined adjacent to the first area AA1. The second area AA2 may be around (e.g., may surround) at least a portion of the first area AA1.

The first area AA1 may be defined as an area of the display module 300, which overlaps the area where the electronic module 400 (refer to FIG. 2A) is disposed in the housing 200. The first area AA1 may have a relatively high light transmittance compared with the second area AA2. FIG. 2A shows the first area AA1 with a circular shape, however, the present disclosure should not be limited thereto or thereby. According to one or more embodiments, the first area AA1 may have various shapes such as a polygonal shape, an oval shape, a shape including at least a curved line, and it should not be particularly limited.

Referring to FIG. 4, the first area AA1 may include display areas BA, line areas BL, and transmission areas BT.

The display areas BA may be arranged along the first direction DR1 and the second direction DR2 in the first area AA1. The display areas BA may be spaced from each other to secure a space where the transmission areas BT are defined within the first area AA1 in a plan view. FIG. 4 shows a structure in which the display areas BA are spaced from each other in the first direction DR1 and the second direction DR2 and arranged along the first direction DR1 and the second direction DR2. However, the display areas BA may be in contact with each other in one direction as long as the space for the transmission areas BT to be defined is secured on the plane. As an example, the display areas BA may be spaced from each other in the first direction DR1 and may be in contact with each other in the second direction DR2.

Each of the display area BA may have a quadrangular shape. FIG. 4 shows a structure in which the display area BA has a rectangular shape with long sides extending in the second direction DR2 and short sides extending in the first direction DR1 as a representative example, however, the shape of the display area BA should not be limited thereto or thereby.

The first pixel EP1 may be defined in the display areas BA.

The first pixel EP1 may include first, second, third-first, and third-second sub-pixels E11, E12, E13a, and E13b. As an example, the first pixel EP1 may include one first sub-pixel E11, one second sub-pixel E12, and two third sub-pixels E13a and E13b.

Two rhombus shapes that are tilted and two rectangular shapes that are tilted, which are defined in the display area BA in FIG. 4, may be shapes of light emitting areas PXA (refer to FIG. 6) defined by an opening OP (refer to FIG. 6) defined through a pixel definition layer PDL (refer to FIG. 6) when viewed in a plane. However, for the convenience of explanation, the tilted rhombus shapes in the display area BA in FIG. 4 are referred to as the first and second sub-pixels E11 and E12, and the tilted rectangular shapes in the display area BA in FIG. 4 are referred to as the third-first and third-second sub-pixels E13a and E13b.

According to one or more embodiments, a plurality of sub-pixels may be disposed in one display area BA. As an example, four sub-pixels may be arranged in one display area BA, and at least two of the four sub-pixels may provide lights having the same color.

As an example, the first, second, third-first, and third-second sub-pixels E11, E12, E13a, and E13b may be arranged to be spaced from each other in one display area BA. As an example, the first sub-pixel E11 and the second sub-pixel E12 may be spaced from each other in the second direction DR2, the third-first sub-pixel E13a and the third-second sub-pixel E13b may be spaced from each other in the second direction DR2, the first sub-pixel E11 may be spaced from one third-first sub-pixel E13a in a fifth direction DR5, and the second sub-pixel E12 may be spaced from the one third-first sub-pixel E13a in a fourth direction DR4.

The first and second sub-pixels E11 and E12 may have the tilted rhombus shape in a plan view. The third sub-pixels E13a and E13b may have the tilted rectangular shape in a plan view. However, the shapes of the first, second, third-first, and third-second sub-pixels E11, E12, E13a, and E13b in a plan view should not be limited thereto or thereby and, according to one or more embodiments, may have a polygonal shape such as a quadrangular shape or a circular shape. The third sub-pixels E13a and E13b may include the third-first sub-pixel E13a having a rectangular shape extending in the fourth direction DR4 and the third-second sub-pixel E13b having a rectangular shape extending in the fifth direction DR5.

The first, second, third-first, and third-second sub-pixels E11, E12, E13a, and E13b may have different light emitting areas from each other. As an example, the light emitting areas of the first, second, third-first, and third-second sub-pixels E11, E12, E13a, and E13b may become larger in the order of the third sub-pixels E13a and E13b, the second sub-pixel E12, and the first sub-pixel E11.

The first sub-pixel E11, the second sub-pixel E12, and the third sub-pixels E13a and E13b may provide different lights from each other. As an example, the first sub-pixel E11 may be configured to emit a red light, the second sub-pixel E12 may be configured to emit a blue light, and the third sub-pixels E13a and E13b may be configured to emit a green light.

The line area BL may be disposed between the display areas BA to connect the display areas BA. In the case where the display areas BA are spaced from each other in the first direction DR1 and the second direction DR2, four line areas BL adjacent to each other may be arranged adjacent to the display area BA. However, from among the line areas BL adjacent to the display areas BA disposed at a boundary of the first area AA1, some line areas BL adjacent to the second area AA2 may be omitted.

The display areas BA and the line areas BL may be areas where a conductive material forming the pixel PX (refer to FIG. 3) is patterned, and thus, when the electronic module 400 (refer to FIG. 2A) transmits/receives a light, the light reflected by the conductive material may deteriorate the performance of the electronic module 400. According to one or more embodiments of the present disclosure, as a light blocking layer BML (refer to FIG. 7) that overlaps the display area BA and the line area BL of the first area AA1 and does not overlap the transmission area BT of the first area AA1 is disposed, the deterioration of the performance of the electronic module 400 may be improved. This will be described in detail later. In FIG. 4, the display area BA and the line area BL in which the light blocking layer BML is disposed in the first area AA1 are shown in a relatively darker color than the transmission area BT.

According to the present embodiment, the transmission area BT may have a shape defined by the display areas BA and the line areas BL included in the first area AA1 in a plan view. As an example, the transmission area BT may correspond to an area surrounded by four display areas BA arranged in the first direction DR1 and the second direction DR2 and the line areas BL disposed between the four display areas BA.

In the present embodiment, the transmission area BT may have a shape obtained by removing a small square shape from each of two bottom corners of a larger square shape.

The transmission area BT may correspond to an area where conductive materials or insulating layers are patterned or are not deposited to improve a light transmittance thereof. Because the first area AA1 includes the transmission areas BT, the first area AA1 may have a relatively high light transmittance compared with the second area AA2 that does not include the transmission areas BT. The light transmitted and/or received by the electronic module 400 (refer to FIG. 2A) may travel through the transmission areas BT.

Referring to FIG. 4, second pixels EP2 may be disposed in the second area AA2.

The second pixel EP2 may include first, second, third-first, and third-second sub-pixels E21, E22, E23a, and E23b. As an example, the second pixel EP2 may include one first sub-pixel E21, one second sub-pixel E22, and two third sub-pixels E23a and E23b. Two rhombus shapes that are tilted and two rectangular shapes that are tilted, which are defined in the second area AA2 in FIG. 4, may be shapes of the light emitting areas PXA (refer to FIG. 6) defined by the opening OP (refer to FIG. 6) defined through the pixel definition layer PDL (refer to FIG. 6) in a plan view. However, for the convenience of explanation, the tilted rhombus shapes in the second area AA2 in FIG. 4 are referred to as the first and second sub-pixels E21 and E22, and the tilted rectangular shapes in the second area AA2 in FIG. 4 are referred to as the third-first and third-second sub-pixels E23a and E23b.

According to one or more embodiments, the sub-pixels may be disposed in the second area AA2. As an example, four sub-pixels may be arranged in the second area AA2, and at least two of the four sub-pixels may provide lights having the same color.

The first, second, third-first, and third-second sub-pixels E21, E22, E23a, and E23b may be arranged to be spaced from each other. As an example, the first sub-pixel E21 and the second sub-pixel E22 may be spaced from each other in the second direction DR2, the third-first sub-pixel E23a and the third-second sub-pixel E23b may be spaced from each other in the second direction DR2, the first sub-pixel E21 may be spaced from the third-first sub-pixel E23a in the fifth direction DR5, and the second sub-pixel E22 may be spaced from the third-first sub-pixel E23a in the fourth direction DR4.

The arrangement of the first, second, third-first, and third-second sub-pixels E21, E22, E23a, and E23b may be substantially the same as the arrangement of the first, second, third-first, and third-second sub-pixels E11, E12, E13a, and E13b. However, a separation distance between the first, second, third-first, and third-second sub-pixels E21, E22, E23a, and E23b may be smaller than a separation distance between the first, second, third-first, and third-second sub-pixels E11, E12, E13a, and E13b.

The first and second sub-pixels E21 and E22 may have tilted rhombus shape in a plan view. The third sub-pixels E23a and E23b may have the tilted rectangular shape in a plan view. However, the shapes of the first, second, third-first, and third-second sub-pixels E21, E22, E23a, and E23b in a plan view should not be limited thereto or thereby and, according to one or more embodiments, may have a polygonal shape such as a quadrangular shape or a circular shape. The third sub-pixels E23a and E23b may include the third-first sub-pixel E23a having the rectangular shape extending in the fourth direction DR4 and the third-second sub-pixel E23b having the rectangular shape extending in the fifth direction DR5.

The first, second, third-first, and third-second sub-pixels E21, E22, E23a, and E23b may have different light emitting areas from each other. As an example, the light emitting areas of the first, second, third-first, and third-second sub-pixels E21, E22, E23a, and E23b may become larger in the order of the third sub-pixels E23a and E23b, the second sub-pixel E22, and the first sub-pixel E21.

The first sub-pixel E21, the second sub-pixel E22, and the third sub-pixels E23a and E23b may provide different lights from each other. As an example, the first sub-pixel E21 may emit the red light, the second sub-pixel E22 may emit the blue light, and the third sub-pixels E23a and E23b may emit the green light.

Because the first area AA1 includes not only the display area BA but also the transmission area BT, a density of the first pixels EP1 arranged in the first area AA1 is less than a density of the second pixels EP2 arranged in the second area AA2.

However, the first pixel EP1 may have a relatively large light emitting area compared with the second pixel EP2. In the case where the sub-pixels emit the lights having the same color, the light emitting area of the first, second, third-first, and third-second sub-pixels E11, E12, E13a, E13b included in the first pixel EP1 may be greater than the light emitting area of the first, second, third-first, and third-second sub-pixels E21, E22, E23a, E23b included in the second pixel EP2. That is, the light emitting area of the first sub-pixel E11 of the first pixel EP1 may be greater than the light emitting area of the first sub-pixel E21 of the second pixel EP2, the light emitting area of the second sub-pixel EP12 of the first pixel EP1 may be greater than the light emitting area of the second sub-pixel E22 of the second pixel EP2, and the light emitting area each of the third sub-pixels E13a and E13b of the first pixel EP1 may be greater than the light emitting area each of the third sub-pixels E23a and E23b of the second pixel EP2. Accordingly, a difference in light emitting amount between the first area AA1 and the second area AA2, which is caused since the density of the first pixels EP1 in the first area AA1 is smaller than the density of the second pixels EP2 in the second area AA2, may be at least partially compensated for.

FIG. 5 is a plan view of a portion of the display area BA and a portion of the line areas BL extending from the display area BA according to one or more embodiments of the present disclosure.

Referring to FIG. 5, the first pixel EP1 may be disposed in the display area BA.

The first pixel EP1 may include the first, second, third-first, and third-second sub-pixels E11, E12, E13a, and E13b. The first sub-pixel E11 may include a first light emitting element LD11 and a first pixel circuit PC11 electrically connected to the first light emitting element LD11, the second sub-pixel E12 may include a second light emitting element LD12 and a second pixel circuit PC12 electrically connected to the second light emitting element LD12, the third-first sub-pixel E13a may include a third-first light emitting element LD13a and a third-first pixel circuit PC13a electrically connected to the third-first light emitting element LD13a, and the third-second sub-pixel E13b may include a third-second light emitting element LD13b and a third-second pixel circuit PC13b electrically connected to the third-second light emitting element LD13b.

For the convenience of explanation, areas in which the first, second, third-first, and third-second pixel circuits PC11, PC12, PC13a, and PC13b are disposed are shown as a dotted rectangle in FIG. 5. Descriptions of the first, second, third-first, and third-second pixel circuits PC11, PC12, PC13a, and PC13b correspond to the above descriptions of the pixel circuit PC (refer to FIG. 3), and thus, details thereof will be omitted.

Referring to FIG. 5, the first, second, third-first, and third-second pixel circuits PC11, PC12, PC13a, and PC13b may be connected to the first, second, third-first, and third-second light emitting elements LD11, LD12, LD13a, and LD13b in a one-to-one correspondence. According to one or more embodiments of the present disclosure, the pixel circuit and the light emitting element, which are connected to each other, may overlap each other, however, they should not be limited thereto or thereby. According to one or more embodiments, the pixel circuit and the light emitting element, which are connected to each other, may be spaced from each other in a plan view and may be connected to each other via a connection line.

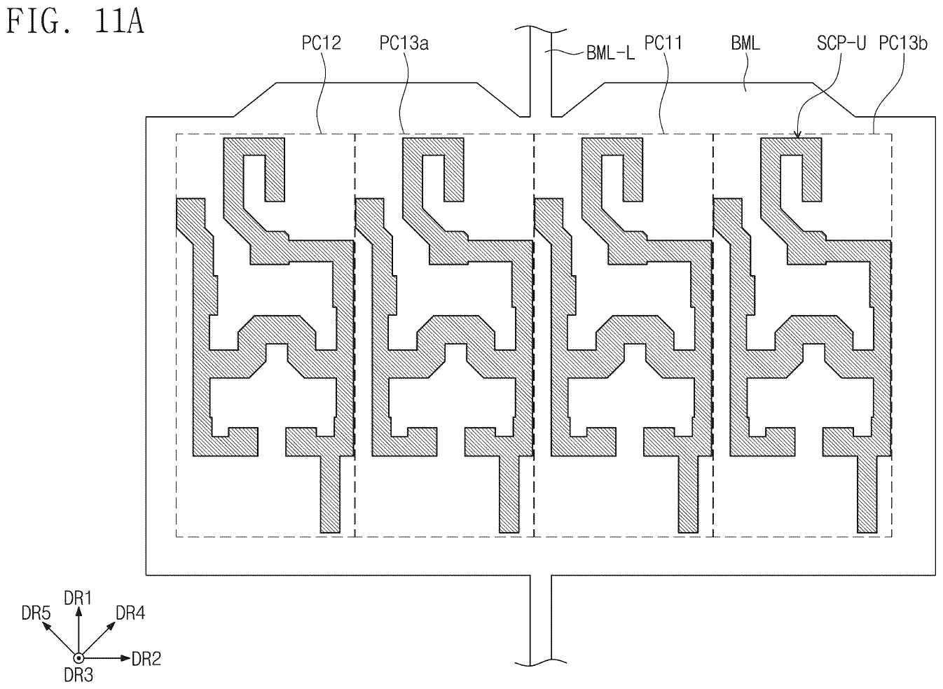

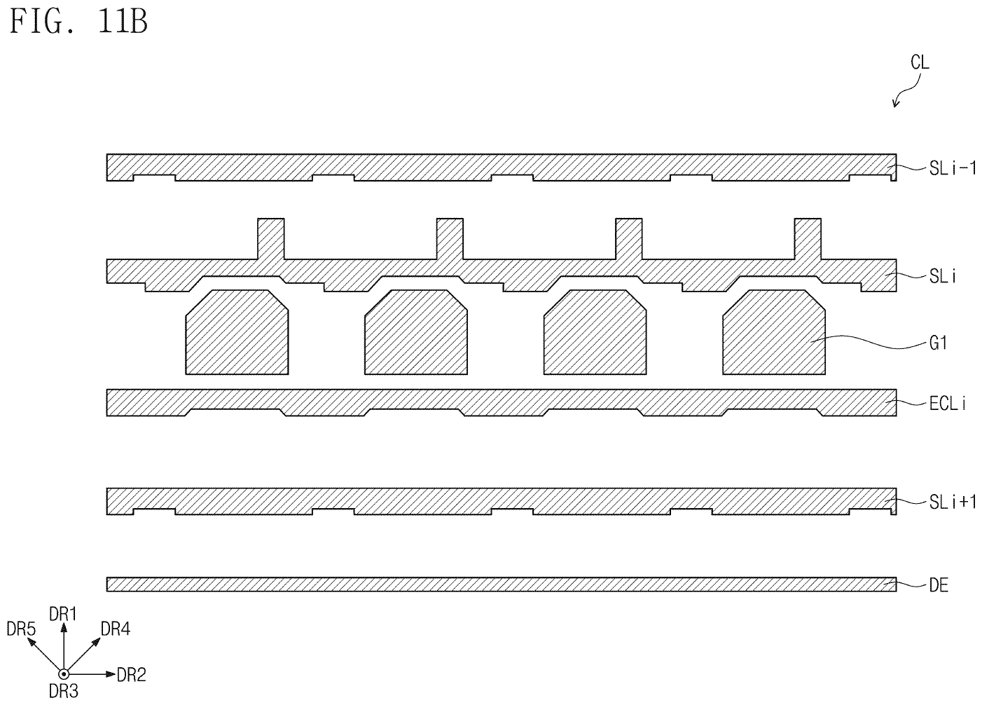

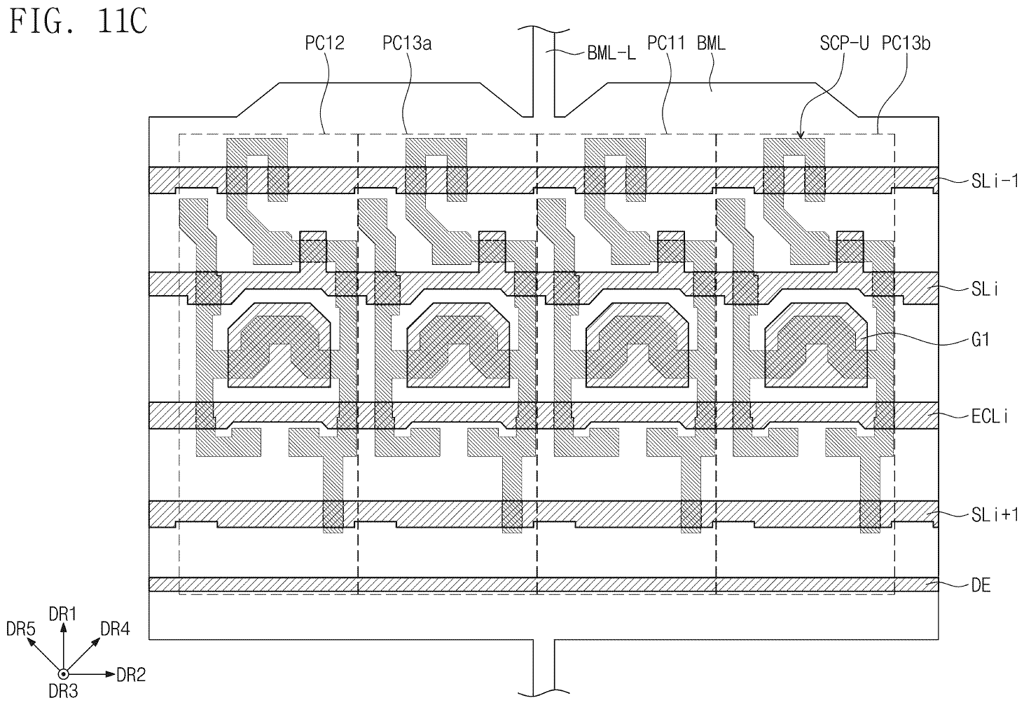

According to one or more embodiments of the present disclosure, The display panel EP may include a dummy electrode DE disposed in the display area BA. The dummy electrode DE may be included in a conductive layer CL (refer to FIG. 11B) included in the display panel, which will be described later. The display area BA may have a rectangular shape defined by short sides extending in the first direction DR1 and long sides extending in the second direction DR2 and connected to the short sides. The dummy electrode DE may be disposed adjacent to a long side disposed at a lower portion of the display area BA of the long sides of the display area BA. The dummy electrode DE may extend in the second direction DR2 and may entirely overlap the first, second, third-first, and third-second pixel circuits PC11, PC12, PC13a, and PC13b.

However, the present disclosure should not be limited thereto or thereby. According to one or more embodiments, the dummy electrode DE may be provided in plural, and the dummy electrodes DE may be disposed to overlap corresponding pixel circuits from among the first, second, third-first, and third-second pixel circuits PC11, PC12, PC13a, and PC13b.

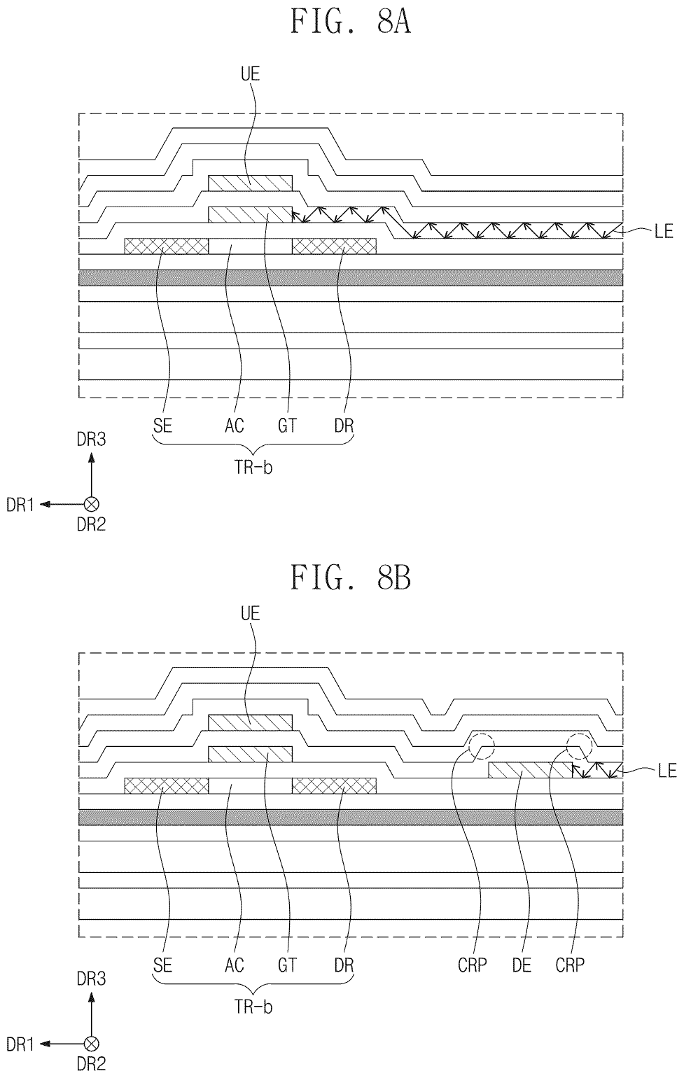

The dummy electrode DE may block a light LE (refer to FIG. 8B) traveling in a direction from the transmission area BT (refer to FIG. 4) to the display area BA and may protect the transistors T1 to T7 (refer to FIG. 3) included in the first, second, third-first, and third-second pixel circuits PC11, PC12, PC13a, and PC13b from the light LE. The dummy electrode DE may block the light LE traveling in the first direction DR1 to the display area BA from the transmission area BT adjacent to the long side disposed at the lower portion of the display area BA.

FIG. 6 is a cross-sectional view taken along the line I-I′ of FIG. 4. FIG. 7 is a cross-sectional view taken along the line II-II′ of FIG. 4. FIG. 8A is a cross-sectional view of a display panel according to a comparative example. FIG. 8B is a cross-sectional view of the display panel according to one or more embodiments of the present disclosure.

Hereinafter, a stack structure in the second area AA2 of the display module 300 will be described with reference to FIG. 6. For the convenience of explanation, FIG. 6 shows only one transistor TR-μ, and other transistors are omitted. The transistor TR-a may correspond to one of the transistors T1 to T7, e.g., first, second, third, fourth, fifth, sixth, and seventh transistors T1, T2, T3, T4, T5, T6, and T7 (refer to FIG. 3).

The display module 300 may include the display panel 310, the input sensor 320, a black matrix BM, a color filter 100, and an overcoat layer OC in an area overlapping the second area AA2.

The display panel 310 may include a circuit element layer DP-CL, a display element layer DP-OLED, and a thin film encapsulation layer 80.

The display panel 310 may further include functional layers such as an anti-reflective layer, a refractive index control layer, and/or the like. The circuit element layer DP-CL may include at least a plurality of insulating layers and a circuit element. Hereinafter, the insulating layers may include an organic layer and/or an inorganic layer. The display panel 310 may include first to seventh insulating layers 10 to 70, however, the present disclosure should not be limited thereto or thereby.

An insulating layer, a semiconductor layer, and a conductive layer may be formed by a coating or depositing process. Then, the insulating layer, the semiconductor layer, and the conductive layer may be selectively patterned by a photolithography process. Accordingly, the semiconductor pattern, the conductive pattern, and the signal line may be formed.

A base layer BS may serve as a base layer on which the other components of the circuit element layer DP-CL are disposed. The base layer BS may have a structure in which a layer including an organic material and a layer including an inorganic material are alternately stacked with each other. As an example, the base layer BS may include a first base layer PI1, a first barrier layer BI, and a second base layer PI2.

The first base layer PI1 may be disposed under the first barrier layer BI. The first base layer PI1 may include an organic material. As an example, the first base layer PI1 may include one or more of polyimide (PI), polyethylene naphthalate (PEN), polyethylene terephthalate (PET), polyarylate, polycarbonate (PC), polyetherimide (PEI), and/or polyethersulfone (PES).

The first barrier layer BI may be disposed on the first base layer PI1. The first barrier layer BI may include an inorganic material. As an example, the first barrier layer BI may include at least one of silicon oxide, silicon oxynitride, aluminum oxide, titanium oxide, silicon nitride, zirconium oxide, and/or hafnium oxide.

The second base layer PI2 may be disposed on the first barrier layer BI. The second base layer PI2 may include an organic material. The organic material included in the second base layer PI2 may be the same as the organic material included in the first base layer BI1.

However, according to one or more embodiments, the base layer BS may be provided in a single-layer structure. In this case, the base layer BS may include a synthetic resin layer. The synthetic resin layer may include a thermosetting resin. In particular, the synthetic resin layer may be a polyimide-based resin layer, however, a material for the synthetic resin layer should not be particularly limited. In addition, the base layer BS may include a glass, metal, or organic/inorganic composite material.

A second barrier layer BRL may be disposed on the base layer BS. The second barrier layer BRL may include an inorganic material. As an example, the second barrier layer BRL may include at least one of silicon oxide, aluminum oxide, titanium oxide, silicon nitride, silicon oxynitride, zirconium oxide, and/or hafnium oxide.

A buffer layer BFL may be disposed on the second barrier layer BRL. The buffer layer BFL may improve an adhesive force between the second barrier layer BRL and the semiconductor pattern and/or between the second barrier layer BRL and the conductive pattern. The buffer layer BFL may include at least one of silicon oxide and/or silicon nitride. In addition, the buffer layer BFL may have a single-layer or multi-layer structure of silicon oxynitride, however, it and should not be thereto or thereby.

A semiconductor pattern may be disposed on the buffer layer BFL. Hereinafter, the semiconductor pattern disposed directly on the buffer layer BFL may be defined as a first semiconductor pattern. The first semiconductor pattern may include silicon semiconductor. As an example, the first semiconductor pattern may include polysilicon and/or amorphous silicon. The first semiconductor pattern may have different electrical properties depending on whether it is doped or not or whether it is doped with an N-type dopant or a P-type dopant. The first semiconductor pattern may include a doped region and a non-doped region. The doped region may be doped with the N-type dopant or the P-type dopant.

A source SE, an active AC, and a drain DR of the transistor TR-a may be formed from the semiconductor pattern. The source SE and the drain DR of the transistor TR-a may be formed to be spaced from each other with the active AC interposed therebetween.

A connection signal line SCL may be disposed on the buffer layer BFL. The connection signal line SCL may be connected to a drain D6 of the sixth transistor T6 (refer to FIG. 3) in a plan view.

A first insulating layer 10 may be an inorganic layer and/or an organic layer and may have a single-layer or multi-layer structure. The first insulating layer 10 may include at least one of aluminum oxide, titanium oxide, silicon oxide, silicon nitride, silicon oxynitride, zirconium oxide, and/or hafnium oxide.

In the present embodiment, the first insulating layer 10 may be disposed on the buffer layer BFL and may cover the first semiconductor pattern and the connection signal line SCL. In the present embodiment, the first insulating layer 10 may have a single-layer structure of silicon oxide (SiOx). Not only the first insulating layer 10, but also an insulating layer of the circuit element layer DP-CL described later may be an inorganic layer and/or an organic layer and may have a single-layer or multi-layer structure. The inorganic layer may include at least one of the above-mentioned materials.

A gate electrode GT of the transistor TR-a may be disposed on the first insulating layer 10. The gate electrode GT may be a portion of a metal pattern. The gate electrode GT of the transistor TR-a may overlap the active AC of the transistor TR-a in the third direction DR3.

A second insulating layer 20 may be disposed on the first insulating layer 10 and may cover the gate electrode GT. The second insulating layer 20 may be an inorganic layer and/or an organic layer and may have a single-layer or multi-layer structure. In the present embodiment, the second insulating layer 20 may be an inorganic layer and/or an organic layer and may have a single-layer structure of silicon nitride (SINx).

An upper electrode UE may be disposed on the second insulating layer 20. The upper electrode UE may overlap the gate electrode GT in the third direction DR3. The upper electrode UE may be a portion of a metal pattern or a portion of the doped semiconductor pattern. A portion of the gate electrode GT and the upper electrode UE overlapping the portion of the gate electrode GT may define the capacitor Cst (refer to FIG. 3). According to one or more embodiments, the upper electrode UE may be omitted.

A third insulating layer 30 may be disposed on the second insulating layer 20 and may cover the upper electrode UE. In the present embodiment, the third insulating layer 30 may have a single-layer structure of silicon oxide (SiOx) or may have a multi-layer structure in which a plurality of silicon oxide (SiOx) layers and a plurality of silicon nitride (SiNx) layers alternately stacked with the silicon oxide layers. In this case, a layer disposed at a lowermost position from among the layers included in the third insulating layer 30 may be the silicon oxide (SiOx) layer.

A semiconductor pattern may be disposed on the third insulating layer 30. Hereinafter, the semiconductor pattern disposed directly on the third insulating layer 30 may be defined as a second semiconductor pattern. The second semiconductor pattern may include metal oxide. The oxide semiconductor may include a crystalline or amorphous oxide semiconductor.

A fourth insulating layer 40 may be disposed on the third insulating layer 30 to cover the second semiconductor pattern. In the present embodiment, the fourth insulating layer 40 may be a silicon nitride (SiNx) layer.

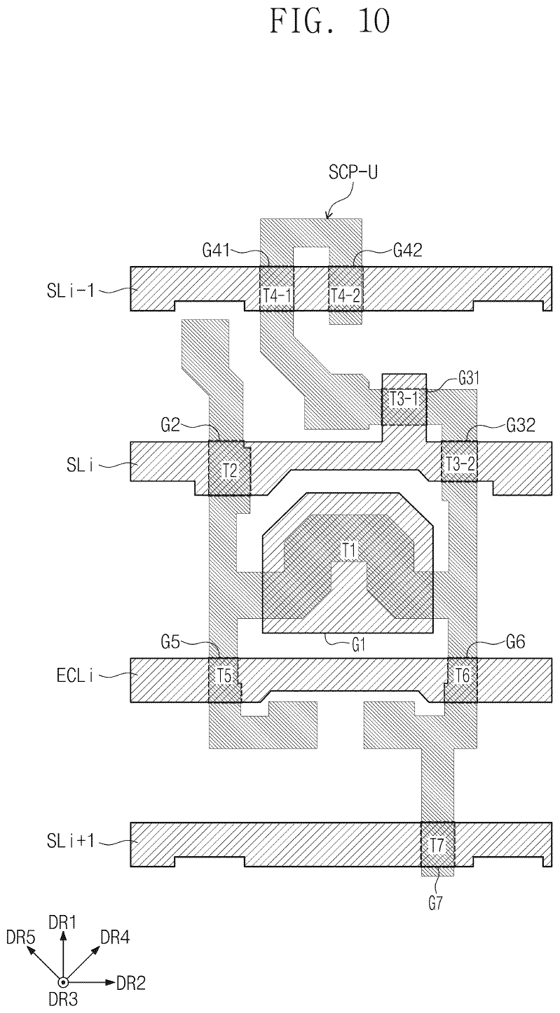

According to one or more embodiments, the fourth insulating layer 40 may be replaced with an insulating pattern. The gate electrodes G31 and G32 (refer to FIG. 10) of the third transistor T3 (refer to FIG. 3) may be disposed on the insulating pattern. In the present embodiment, the gate electrode G31 and G32 (refer to FIG. 10) may have the same shape as that of the insulating pattern in a plan view.

A fifth insulating layer 50 may be disposed on the fourth insulating layer 40 to cover the gate electrodes G31 and G32 (refer to FIG. 10). In the present embodiment, the fifth insulating layer 50 may include a silicon oxide layer and a silicon nitride layer. The fifth insulating layer 50 may include a plurality of silicon oxide layers and a plurality of silicon nitride layers alternately staked with the silicon oxide layers.

In one or more embodiments, a source, a drain, and a gate electrode of the fourth transistor T4 (refer to FIG. 3) may be formed through the same process as those of the source, the drain, and the gate electrode G31 and G32 (refer to FIG. 10) of the third transistor T3, respectively.

At least one insulating layer may be further disposed on the fifth insulating layer 50. As the present embodiment, a sixth insulating layer 60 and a seventh insulating layer 70 may be disposed on the fifth insulating layer 50. Each of the sixth insulating layer 60 and the seventh insulating layer 70 may be an organic layer and may have a single-layer or multi-layer structure. Each of the sixth insulating layer 60 and the seventh insulating layer 70 may have a single-layer structure of a polyimide-based resin layer.

However, it should not be limited thereto or thereby. According to one or more embodiments, each of the sixth insulating layer 60 and the seventh insulating layer 70 may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and/or a perylene-based resin.

A first connection electrode CNE1 may be disposed on the fifth insulating layer 50. The first connection electrode CNE1 may be connected to the connection signal line SCL (or a connection electrode) via a first contact hole CH1 defined through the first to fifth insulating layers 10 to 50.

A second connection electrode CNE2 may be disposed on the sixth insulating layer 60. The second connection electrode CNE2 may be connected to the first connection electrode CNE1 via a second contact hole CH-60 defined through the sixth insulating layer 60.

A first light emitting element LD21 may be disposed on the seventh insulating layer 70. The first light emitting element LD21 may include a first electrode AE, a hole control layer HCL, a light emitting layer EML, an electron control layer ECL, and a second electrode CD, which are sequentially stacked in the third direction DR3.

The first electrode AE of the first light emitting element LD21 may be disposed on the seventh insulating layer 70. The pixel definition layer PDL may be disposed on the seventh insulating layer 70. The pixel definition layer PDL may be provided with an opening OP defined therethrough. At least a portion of the first electrode AE may be exposed through the opening OP of the pixel definition layer PDL.

As shown in FIG. 6, the second area AA2 of the display module 300 may include a light emitting area PXA and a non-light-emitting area NPXA adjacent to the light emitting area PXA. The non-light-emitting area NPXA may be around (e.g., may surround) the light emitting area PXA. In the present embodiment, the light emitting area PXA may be defined to correspond to the first electrode AE exposed through the opening OP.

The first sub-pixel E21 may include the first light emitting element LD21 and the first to seventh transistors T1 to T7 (refer to FIG. 3) connected to the first light emitting element LD21.

In the present embodiment, the light emitting area PXA may be defined to correspond to the first electrode AE exposed through the opening OP. In the present embodiment, a patterned light emitting layer EML is shown as a representative example, however, the light emitting layer EML may be commonly disposed over the pixels PX. In this case, the light emitting layer EML may generate a white light or a green light. In addition, the light emitting layer EML may have a multi-layer structure.

An electron control layer ECL may be disposed on the light emitting layer EML. The electron control layer ECL may include an electron transport layer and an electron injection layer. The second electrode CE may be disposed on the electron control layer ECL. The electron control layer ECL, the hole control layer HCL, and the second electrode CE may be commonly disposed in the pixels PX.

The thin film encapsulation layer 80 may be disposed on the second electrode CE. The thin film encapsulation layer 80 may be commonly disposed over the pixels PX. In the present embodiment, the thin film encapsulation layer 80 may directly cover the second electrode CE.

The thin film encapsulation layer 80 may be disposed on the first light emitting element LD21. The thin film encapsulation layer 80 may include a first inorganic layer 81, an organic layer 82, and a second inorganic layer 83, however, it should not be limited thereto or thereby. According to one or more embodiments, the thin film encapsulation layer 80 may further include a plurality of inorganic layers and a plurality of organic layers.

The first inorganic layer 81 may be in contact with the second electrode CE. The first inorganic layer 81 may prevent external moisture or oxygen from entering the light emitting layer EML. As an example, the first inorganic layer 81 may include silicon nitride, silicon oxide, or a combination thereof. The first inorganic layer 81 may be formed through a deposition process.

The organic layer 82 may be disposed on the first inorganic layer 81 and may be in contact with the first inorganic layer 81. The organic layer 82 may provide a flat surface on the first inorganic layer 81. An uneven shape formed on an upper surface of the first inorganic layer 81 or particles existing on the first inorganic layer 81 may be covered by the organic layer 82, and thus, an influence of a surface state of the upper surface of the first inorganic layer 81, which is exerted on components formed on the organic layer 82, may be blocked. The organic layer 82 may include an organic material and may be formed by a solution process, such as a spin coating, a slit coating, or an inkjet process.

The second inorganic layer 83 may be disposed on the organic layer 82 to cover the organic layer 82. The second inorganic layer 83 may be stably formed on a relatively flat surface than being disposed on the first inorganic layer 81. The second inorganic layer 83 may encapsulate moisture leaked from the organic layer 82 to prevent the moisture from flowing from the outside. The second inorganic layer 83 may include silicon nitride, silicon oxide, or a compound thereof. The second inorganic layer 83 may be formed by a deposition process.

The input sensor 320 may be disposed directly on the thin film encapsulation layer 80. The input sensor 320 may include a plurality of conductive patterns MS1 and MS2 and first, second, and third sensing insulating layers 91, 92, and 93.

Each of the first sensing insulating layer 91, the second sensing insulating layer 92, and the third sensing insulating layer 93 may include at least one of an inorganic material and an organic material.

The first sensing insulating layer 91 may be disposed on the thin film encapsulation layer 80. First conductive patterns MS1 may be disposed on the first sensing insulating layer 91 and may be covered by the second sensing insulating layer 92. Second conductive patterns MS2 may be disposed on the second sensing insulating layer 92 and may be covered by the third sensing insulating layer 93.

Each of the first and second conductive patterns MS1 and MS2 may have a conductivity. Each of the first and second conductive patterns MS1 and MS2 may have a single-layer structure or a multi-layer structure and should not be limited thereto or thereby. At least one of the first conductive patterns MS1 and the second conductive patterns MS2 may be provided as mesh lines in a plan view.

The mesh lines forming the conductive patterns MS1 and MS2 may be spaced from the light emitting layer EML in a plan view. Accordingly, although the input sensor 320 is directly formed on the display panel 310, the light generated by the pixels PX (refer to FIG. 2B) of the display panel 310 may be provided to the user without being interfered by the input sensor 320.

The color filter 100 may overlap the light emitting layer EML in the third direction DR3. The color filter 100 may selectively transmit a light corresponding to a light provided from the light emitting layer EML. As an example, when the light emitting layer EML provides a green light, the color filter 100 may be a green color filter that transmits the green light.

The color filter 100 may include a polymer photosensitive resin and a pigment or dye. As an example, the color filter 100 overlapping the light emitting layer EML providing the green light may include a green pigment or dye, the color filter 100 overlapping the light emitting layer EML providing the blue light may include a blue pigment or dye, and the color filter 100 overlapping the light emitting layer EML providing the red light may include a red pigment or dye.

However, it should not be limited thereto or thereby, and the color filter 100 overlapping the light emitting layer EML providing the green light may not include the pigment or dye. In this case, the color filter 100 may be transparent, and the color filter 100 may be formed of a transparent photosensitive resin.

The black matrix BM may be disposed between the color filters providing different lights from each other. The black matrix BM may be a pattern with a black color, e.g., a matrix having a lattice shape. The black matrix BM may include a black coloring agent. The black coloring agent may include a black pigment or a black dye. The black coloring agent may include a metal material, such as carbon black, chrome, etc., or an oxide thereof.

The overcoat layer OC may be disposed on the color filter 100 and the black matrix BM. The overcoat layer OC may cover concave-convex portions occurring when the color filter 100 and the black matrix BM are formed to provide a flat surface. That is, the overcoat layer OC may be a planarization layer. The window WM described with reference to FIG. 2A may be coupled to the overcoat layer OC that provides the flat surface by an adhesive layer.

FIG. 7 is a cross-sectional view of a portion of each of the display area BA and the transmission area BT of the first area AA1 of the display module 300. FIG. 8A is a cross-sectional view of a display panel according to a comparative example. FIG. 8B is a cross-sectional view of the display panel according to one or more embodiments of the present disclosure.

Hereinafter, a stack structure in the first area AA1 of the display module 300 will be described with reference to FIG. 7. FIG. 7 shows only one transistor TR-b, and other transistors are omitted. For the convenience of explanation, a source SE, a drain DR, and an active AC of the transistor TR-b are shown as being directly disposed on the buffer layer BFL. The transistor TR-b may correspond to one of the transistors T1 to T7 described with reference to FIG. 3.

The display module 300 may include the display panel 310, the input sensor 320, the black matrix BM, the color filter 100, and the overcoat layer OC in an area overlapping the first area AA1.

The display panel 310 may include the circuit element layer DP-CL, the display element layer DP-OLED, and the thin film encapsulation layer 80.

The first pixel EP1 (refer to FIG. 4) disposed in the first area AA1 may include the first to seventh transistors T1 to T7 (refer to FIG. 3) connected to the light emitting element LD13a, and a stack structure of the first pixel EP1 may correspond to the stack structure of the second pixel EP2 disposed in the second area AA2 described with reference to FIG. 6. Accordingly, details of the same elements described with reference to FIG. 6 will not be repeated in FIG. 7.

The light blocking layer BML may be disposed in the display area BA of the first area AA1. That is, the light blocking layer BML may overlap the display area BA and may not overlap the transmission area BT of the first area AA1. The light blocking layer BML may be disposed between the second barrier layer BRL and the buffer layer BFL. However, in a case where the second barrier layer BRL is omitted, the light blocking layer BML may be disposed between the base layer BS and the buffer layer BFL and should not be particularly limited. The light blocking layer BML may include a metal material.

As the light blocking layer BML is disposed on the second barrier layer BRL, a defect in which the conductive materials disposed on the base layer BS and the second barrier layer BRL are viewed as the electronic module 400 due to the external light may be prevented. Accordingly, even though the electronic module 400 is disposed in the active area AA (refer to FIG. 2A), interference between the electronic module 400 and the conductive materials disposed on the base layer BS and the second barrier layer BRL may be reduced or minimized, and thus, the performance of the electronic module 400 of the electronic device 1000 may be improved.

In the transmission area BT, portions of the first to seventh insulating layers 10 to 70, which overlap the transmission area BT, may be omitted. As an example, the portions of the first to seventh insulating layers 10 to 70, which overlap the transmission area BT, may not be deposited or may be removed through a patterning process after being deposited.

According to the present embodiment, an upper surface BM-U of the black matrix BM, which is adjacent to the transmission area BT, may be exposed without being covered by the color filter 100 and may be in contact with the overcoat layer OC.

The organic layer 82 of the thin film encapsulation layer 80 may have different thicknesses depending on areas thereof to compensate for a step difference in the portions of the insulating layers, which are not deposited or removed through the patterning process after being deposited in the transmission area BT. As an example, the thickness of the organic layer 82 overlapping the transmission area BT may be greater than the thickness of the organic layer 82 overlapping the second area AA2 and the display area BA.

According to one or more embodiments of the present disclosure, as the electronic device 1000 includes the display panel 310 in which the portions of the insulating layers 10 to 70 are removed in the area overlapping the electronic module 400, the light transmittance of the display module 300 may be improved. Accordingly, even though the electronic module 400 is disposed in the active area AA (refer to FIG. 2A), the performance of the electronic module 400 of the electronic device 1000 may be improved.

The dummy electrode DE may be disposed on (e.g., at) the same layer as the gate electrode GT. The structure that the dummy electrode DE and the gate electrode GT are disposed on (e.g., at) the same layer means that the layer on which the dummy electrode DE is directly disposed is the same as the layer on which the gate electrode GT is directly disposed and does not mean that a position of the dummy electrode DE in the third direction DR3 is the same as a position of the gate electrode GT in the third direction DR3. The dummy electrode DE may be disposed closer to the transmission area BT than the gate electrode GT is.

FIG. 7 shows the structure in which the dummy electrode DE and the gate electrode GT are disposed on the same first insulating layer 10 and the gate electrode GT is disposed in the first direction DR1 with respect to the dummy electrode DE.

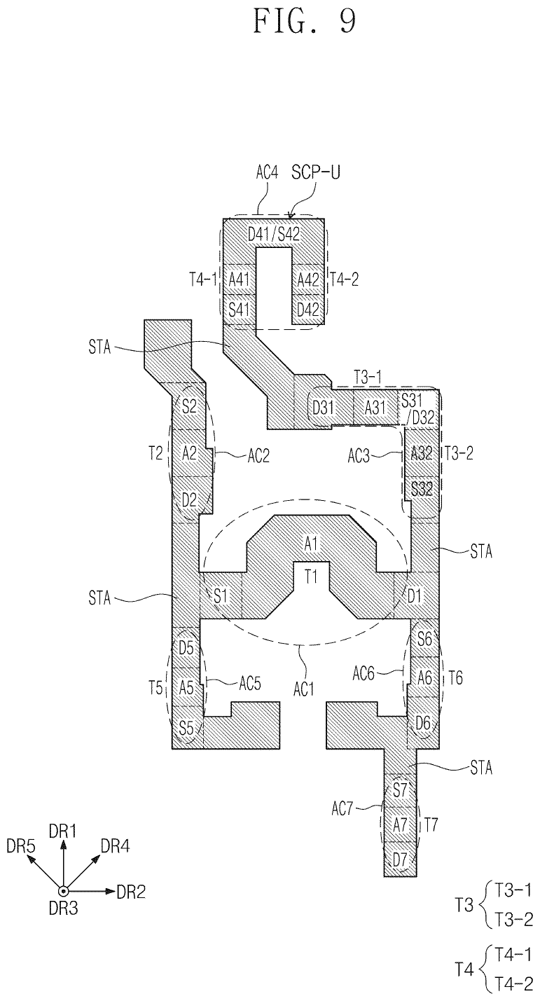

When viewed in a direction from the transmission area BT to the pixel circuit PC (refer to FIG. 3), at least a portion of a semiconductor pattern unit SCP-U (refer to FIG. 9) may be blocked by the dummy electrode DE.

When viewed in the direction from the transmission area BT to the pixel circuit PC, the dummy electrode DE may overlap at least two semiconductor patterns.

The dummy electrode DE may be formed through the same process as a photolithography process to form the gate electrode GT in a manufacturing process of the display module 300. In a case where a mask used to form the gate electrode GT includes not only a pattern required to form the gate electrode GT but also a pattern required to form the dummy electrode DE, both the gate electrode GT and the dummy electrode DE may be formed through one process. Accordingly, the dummy electrode DE is easily formed without adding a separate process, and thus, cost and time required to additionally form the dummy electrode DE may be reduced. In addition, the shape of the dummy electrode DE may be easily designed by changing the shape of the pattern to form the dummy electrode DE. The dummy electrode DE and the gate electrode GT may be formed through the same photolithography process, and thus, the dummy electrode DE and the gate electrode GT may include the same material.

The second insulating layer 20 may be disposed on the first insulating layer 10 to cover the gate electrode GT and the dummy electrode DE, and the third insulating layer 30 may be disposed on the second insulating layer 20 and may cover the second insulating layer 20.

As the second insulating layer 20 covers the dummy electrode DE, at least one curved portion CRP may be formed in the second insulating layer 20 at a position where at least a portion of the second insulating layer 20 overlaps the dummy electrode DE in the third direction DR3. FIG. 7 shows a structure in which two curved portions CRP are formed at the position where the second insulating layer 20 overlaps the dummy electrode DE when viewed in a cross-section. However, the shape of the curved portion CRP should not be limited to the shape shown in FIG. 7 and may be provided in various ways depending on the shape of the dummy electrode DE.

The curved portion CRP may provide curves to the second insulating layer 20 and may effectively block the light LE (refer to FIG. 8B) entering the second insulating layer 20. This will be described in detail later.

FIG. 8A is a cross-sectional view of the display panel according to a comparative example. FIG. 8B is a cross-sectional view of the display panel according to one or more embodiments of the present disclosure. Hereinafter, functions and effects of the dummy electrode DE will be described with reference to FIGS. 8A and 8B.

FIG. 8A shows the comparative example in which a light LE reaches a transistor TR-b through a second insulating layer 20 (refer to FIG. 7). Because a display module 300 (refer to FIG. 7) includes a transmission area BT (refer to FIG. 7) in a first area AA1, the light LE generated in the display module 300 or a light generated outside the display module 300 may reach the transistor TR-b. As an example, the light generated outside the display module 300 may enter the display module 300, or the light LE generated in a light emitting module LM (refer to FIG. 2B) of the display module 300 may reach the transistor TR-b after being scattered, diffracted, and reflected.

The light LE entering through the second insulating layer 20 (refer to FIG. 7) may reach the transistor TR-b. For an example, a refractive index of the second insulating layer 20 may be greater than a refractive index of a first insulating layer 10 (refer to FIG. 7) and a refractive index of a third insulating layer 30 (refer to FIG. 7). In this case, the light LE entering the second insulating layer 20 may travel from the transmission area BA (refer to FIG. 7) to the transistor TR-b in the second insulating layer 20 due to a total-reflection phenomenon caused by a difference in the refractive index between the first, second, and third insulating layers 10, 20, and 30 (refer to FIG. 7). Accordingly, the light LE entering the second insulating layer 20 may easily reach the transistor TR-b.

In the case where the light LE reaches the transistor TR-b, the transistor TR-b may be photo-degraded by energy of the light LE, and characteristics of the transistor TR-b may be deteriorated. As a result, the reliability of the display module 300 (refer to FIG. 7) may be lowered.

FIG. 8B shows a structure in which the light LE entering the second insulating layer 20 (refer to FIG. 7) is blocked by the dummy electrode DE and does not reach the transistor TR-b.

Referring to FIG. 8B, the dummy electrode DE may block at least a portion of a path through which the light LE travels. Accordingly, the light LE entering the second insulating layer 20 (refer to FIG. 7) may be absorbed by the dummy electrode DE or reflected by the dummy electrode DE. Thus, an amount of the light LE reaching the transistor TR-b may be significantly reduced by the dummy electrode DE.

As the dummy electrode DE is provided, the curved portion CRP may be formed in the second insulating layer 20 (refer to FIG. 7). The curved portion CRP of the second insulating layer 20 may increase a structural complexity of the second insulating layer 20. In this case, the expression “the structural complexity of the second insulating layer 20 increases” used herein means that the second insulating layer 20 includes portions with various shapes in addition to flat portions instead of including only the flat portions. Because the structural complexity of the second insulating layer 20 increases due to the curved portion CRP, the amount of the light LE entering the second insulating layer 20 and reaching the transistor TR-b may be significantly reduced. In addition, the curved portion may be formed in the third, fourth, fifth, sixth, and seventh insulating layers 30, 40, 50, 60, and 70 (refer to FIG. 7) disposed on the second insulating layer 20, and thus, the curved portion may block a light entering a corresponding insulating layer from among the third, fourth, fifth, sixth, and seventh insulating layers 30, 40, 50, 60, and 70 (refer to FIG. 7).

FIG. 9 is a plan view of the semiconductor pattern unit according to one or more embodiments of the present disclosure. FIG. 10 is a plan view illustrating an overlapping relationship between the semiconductor pattern unit and the conductive layer according to one or more embodiments of the present disclosure.

For the convenience of explanation, FIG. 9 shows only one semiconductor pattern unit SCP-U forming the semiconductor pattern. The semiconductor pattern may include the semiconductor pattern units SCP-U arranged in a certain rule.

The semiconductor pattern may be disposed on the base layer BS (refer to FIG. 6). The semiconductor pattern unit SCP-U may include first to seventh semiconductor areas AC1 to AC7 respectively corresponding to the first to seventh transistors T1 to T7 (refer to FIG. 3).

Although not shown in FIG. 3, as shown in FIG. 9, the third transistor T3 may include two transistors T3-1 (having S31, A31, D31, and G31) and T3-2 (having S32, A32, D32, and G32), and the fourth transistor T4 may include two transistors T4-1 (having S41, A41, D41, and G41) and T4-2 (having S42, A42, D42, and G42).

Each of the first to seventh semiconductor areas AC1 to AC7 may include a corresponding source from among sources S1 to S7, a corresponding active from among actives A1 to A7, and a corresponding drain from among drains D1 to D7. The sources S1 to S7 and the drains D1 to D7 may have a high doping concentration, and thus may be areas with a conductivity. The actives A1 to A7 may have a low doping concentration and may be disposed between the sources S1 to S7 and the drains D1 to D7.

Hereinafter, the conductive layer CL (refer to FIG. 11B) disposed on the semiconductor pattern and an overlapping relationship between the semiconductor pattern and the conductive layer CL will be described with reference to FIG. 10. The display panel may include a conductive layer CL.

The conductive layer CL (refer to FIG. 11B) may include scan lines SLi−1, SLi, and SLi+1, an emission control line ECLi, and a first gate electrode G1, which extend in the second direction DR2. In addition, the conductive layer CL may further include the dummy electrode DE (refer to FIG. 11B).

FIG. 10 shows only a portion of the conductive layer CL overlapping one semiconductor pattern unit SCP-U, however, the conductive layer CL may extend in the second direction DR2 as the conductive layer CL shown in FIG. 11B and may overlap the plural semiconductor pattern units SCP-U. This will be described in detail later.

A portion of an i-th scan line SLi overlapping the semiconductor pattern unit SCP-U may be a gate electrode G2 of the second transistor T2, another portion of the i-th scan line SLi may be a gate electrode G31 of one third transistor T3-1, and the other portion of the i-th scan line SLi may be a gate electrode G32 of the other third transistor T3-2.

FIG. 10 shows gate electrodes G41 and G42 of fourth transistors T4-1 and T4-2 disposed in an (i−1)th scan line SLi−1, a gate electrode G7 of the seventh transistor T7 disposed in an (i+1)th scan line SLi+1, and a gate electrode G5 of the fifth transistor T5 and a gate electrode G6 of the sixth transistor T6 disposed in an i-th emission control line ECLi.

FIGS. 11A, 11B, and 11C are plan views respectively illustrating the semiconductor pattern, the conductive layer, and a stack structure of the semiconductor pattern and the conductive layer according to one or more embodiments of the present disclosure. Hereinafter, an overlapping relationship between the light blocking layer BML, the semiconductor pattern units SCP-U disposed on the light blocking layer BML, and the conductive layer CL will be described with reference to FIGS. 11A to 11C.

For the convenience of explanation, in FIGS. 11A and 11C, areas in which the first, second, third-first, and third-second pixel circuits PC11, PC12, PC13a, and PC13b described with reference to FIG. 5 are disposed are indicated by a dotted-line quadrangular shape, and the dotted-line quadrangular shape may correspond to the quadrangular shape indicated by a dotted line shown in FIG. 5.

The light blocking layer BML may be provided in plural, and the light blocking layers BML may be disposed on the base layer BS (refer to FIG. 7). A light blocking layer connection line BML-L may be disposed between the light blocking layers BML and may connect two light blocking layers BML to each other. The light blocking layer connection line BML-L may overlap the line area BL (refer to FIG. 4).

The semiconductor pattern including the semiconductor pattern units SCP-U may be disposed on the light blocking layer BML. Four semiconductor pattern units SCP-U may be disposed on one light blocking layer BML. Descriptions about each of the semiconductor pattern units SCP-U shown in FIG. 11A are substantially the same as the descriptions about the semiconductor pattern unit SCP-U with reference to FIG. 9, and thus, details thereof will be omitted.

FIG. 11B shows the conductive layer CL that is disposed on the light blocking layer BML and the semiconductor pattern units SCP-U shown in FIG. 11A. The conductive layer CL may include the scan lines SLi−1, SLi, and SLi+1, the emission control line ECLi, and the dummy electrode DE, which extend in the second direction DR2, and the first gate electrodes G1. The scan lines SLi−1, SLi, and SLi+1 and the emission control line ECLi shown in FIG. 11B may correspond to the shape of the scan lines SLi−1, SLi, and SLi+1, the emission control line ECLi described with reference to FIG. 10, which extends in the second direction DR2.

Descriptions about the scan lines SLi−1, SLi, and SLi+1, the emission control line ECLi, and the first gate electrodes G1 are substantially the same as those described with reference to FIG. 10, and thus, details thereof will be omitted.

The dummy electrode DE may be disposed on (e.g., at) the same layer as the scan lines SLi−1, SLi, and SLi+1, the emission control line ECLi, and the first gate electrodes G1 in a plan view. In addition, the dummy electrode DE may be disposed in a direction opposite to the first direction DR1 with respect to the scan lines SLi−1, SLi, and SLi+1, the emission control line ECLi, and the first gate electrodes G1 in a plan view. Accordingly, the dummy electrode DE may block the light LE (refer to FIG. 8B) traveling from the transmission area BT (refer to FIG. 7) to the display area BA (refer to FIG. 7) and may protect the semiconductor pattern from the light LE.

The dummy electrode DE may extend in one direction in a plan view and may have a continuous shape. FIG. 11B shows the dummy electrode DE extending in the second direction DR2 and having the continuous shape as a representative example, however, the shape of the dummy electrode DE should not be limited thereto or thereby.

In a plan view, the scan lines SLi−1, SLi, and SLi+1, the emission control line ECLi, and the first gate electrodes G1 may overlap the semiconductor pattern units SCP-U, and the dummy electrode DE may be spaced from the semiconductor pattern units SCP-U. FIG. 11C shows the structure in which the dummy electrode DE is spaced from the semiconductor pattern units SCP-U in the first direction DR1 as a representative example.

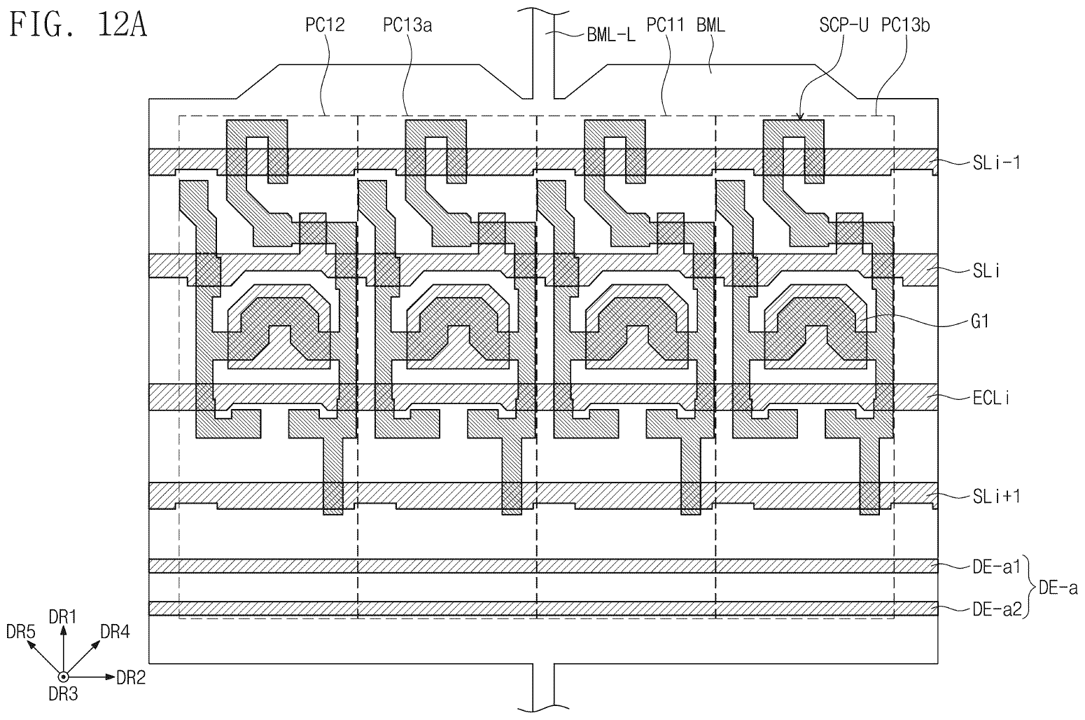

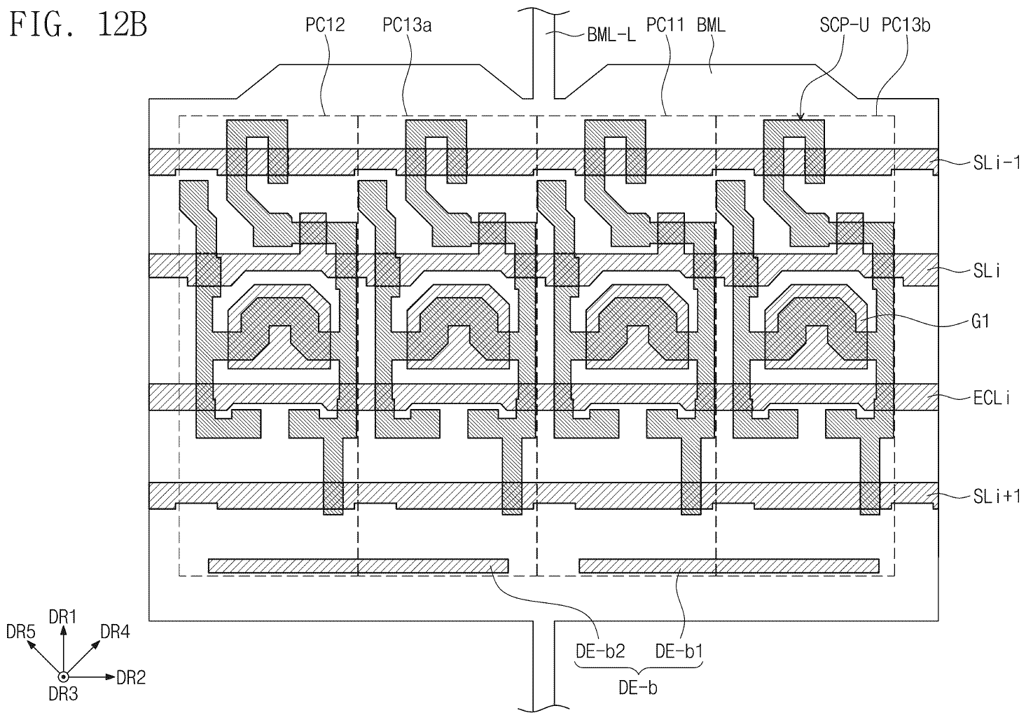

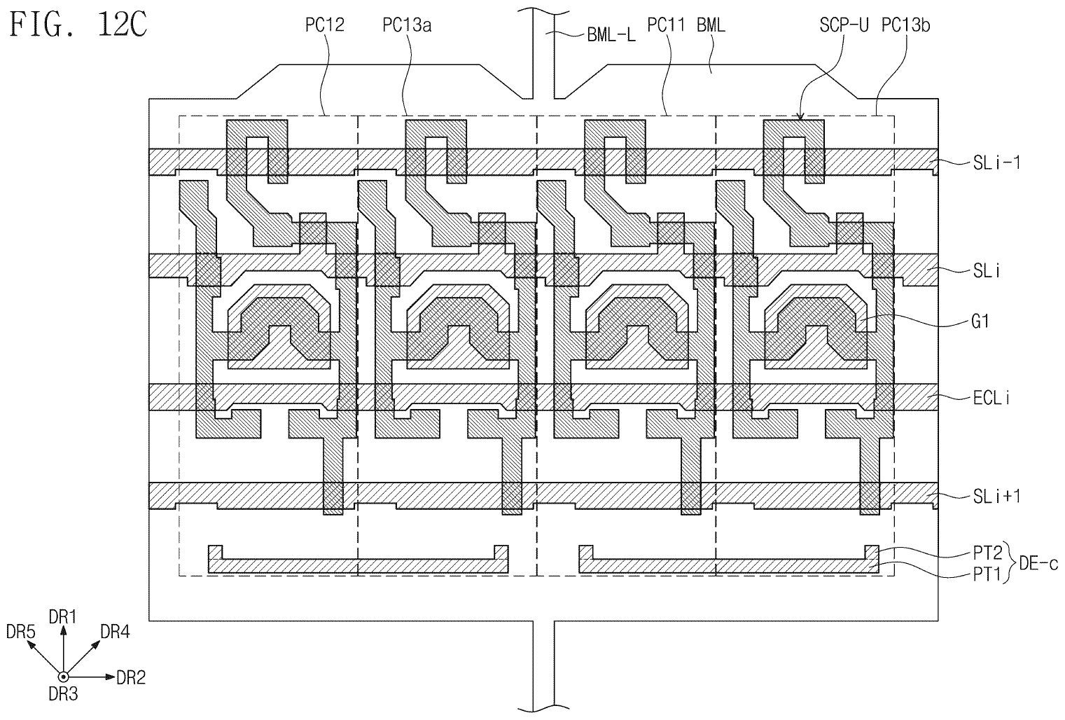

FIG. 12A is a plan view of a display module according to one or more embodiments of the present disclosure.

For the convenience explanation, in FIG. 12A, areas in which first, second, third-first, and third-second pixel circuits PC11, PC12, PC13a, and PC13b described with reference to FIG. 5 are disposed are indicated by a dotted-line quadrangular shape.

The display module may include a light blocking layer BML, a light blocking layer connection line BML-L, semiconductor pattern units SCP-U, scan lines SLi−1, SLi, and SLi+1, an emission control line ECLi, first gate electrodes G1, and a dummy electrode DE-a. In FIG. 12A, descriptions about the light blocking layer BML, the light blocking layer connection line BML-L, the semiconductor pattern units SCP-U, the scan lines SLi−1, SLi, and SLi+1, the emission control line ECLi, and the first gate electrodes G1 are substantially the same as those described with reference to FIGS. 10 to 11C, and thus, descriptions hereinafter will be focused on different features of the dummy electrode DE-a.

The dummy electrode DE-a may include a plurality of sub-dummy electrodes DE-a1 and DE-a2. FIG. 12A shows a structure in which the dummy electrode DE-a includes a first sub-dummy electrode DE-a1 and a second sub-dummy electrode DE-a2. However, the number of the sub-dummy electrodes should not be limited to two and may be three or more.

The sub-dummy electrodes DE-a1 and DE-a2 may be spaced from each other. FIG. 12A shows a structure in which the first sub-dummy electrode DE-a1 is spaced from the second sub-dummy electrode DE-a2 in the first direction DR1. Accordingly, when viewed in a direction from the transmission area BT (refer to FIG. 5) to the pixel circuits PC11, PC12, PC13a, and PC13b, the sub-dummy electrodes DE-a1 and DE-a2 may partially overlap each other.

FIG. 12A shows a structure in which the first sub-dummy electrode DE-a1 and the second sub-dummy electrode DE-a2 have substantially the same shape in a plan view as a representative example, however, the present disclosure should not be limited thereto or thereby. According to one or more embodiments, the sub-dummy electrodes DE-a1 and DE-a2 may have different shapes from each other.

As the dummy electrode DE-a includes the plural sub-dummy electrodes DE-a1 and DE-a2, the number of curved portions CRP (refer to FIG. 7) included in a second insulating layer 20 (refer to FIG. 7) may be greater than that when the dummy electrode DE (refer to FIG. 7) is provided in a single form. Accordingly, the structural complexity of the second insulating layer 20, which is caused by the curved portion CRP, increases, and thus, the amount of a light LE (refer to FIG. 7) entering the second insulating layer 20 and reaching first to seventh transistors T1 to T7 (refer to FIG. 3) may be significantly reduced.

FIG. 12B is a plan view of a display module according to one or more embodiments of the present disclosure.

For the convenience explanation, in FIG. 12B, areas in which first, second, third-first, and third-second pixel circuits PC11, PC12, PC13a, and PC13b described with reference to FIG. 5 are disposed are indicated by a dotted-line quadrangular shape.

The display module may include a light blocking layer BML, a light blocking layer connection line BML-L, semiconductor pattern units SCP-U, scan lines SLi−1, SLi, and SLi+1, an emission control line ECLi, first gate electrodes G1, and a dummy electrode DE-b. In FIG. 12B, descriptions about the light blocking layer BML, the light blocking layer connection line BML-L, the semiconductor pattern units SCP-U, the scan lines SLi−1, SLi, and SLi+1, the emission control line ECLi, and the first gate electrodes G1 are substantially the same as those described with reference to FIGS. 10 to 11C, and thus, descriptions hereinafter will be focused on different features of the dummy electrode DE-b.

The dummy electrode DE-b may include a plurality of sub-dummy electrodes DE-b1 and DE-b2. FIG. 12B shows the structure in which the dummy electrode DE-b includes a first sub-dummy electrode DE-b1 and a second sub-dummy electrode DE-b2 as a representative example. However, the number of the sub-dummy electrodes should not be limited to two and may be three or more.

The sub-dummy electrodes DE-b1 and DE-b2 may be spaced from each other in one direction (e.g., the second direction DR2) and may be disposed to be aligned to each other in a direction different from the one direction (e.g., the first direction DR1). According to FIG. 12B, the first sub-dummy electrode DE-b1 and the second sub-dummy electrode DE-b2 are spaced from each other in the second direction DR2 and are disposed to be aligned to each other in the first direction DR1. However, the present disclosure should not be limited thereto or thereby, and the first sub-dummy electrode DE-b1 and the second sub-dummy electrode DE-b2 may not be aligned to each other in one direction as long as they may block a light LE (refer to FIG. 8B) traveling to a semiconductor pattern.

FIG. 12B shows the structure in which the first sub-dummy electrode DE-b1 and the second sub-dummy electrode DE-b2 have substantially the same shape in a plan view, however, the present disclosure should not be limited thereto or thereby. According to one or more embodiments, the sub-dummy electrodes DE-b1 and DE-b2 may have different shapes from each other.

As the dummy electrode DE-b is not continuous in the one direction and includes the sub-dummy electrodes DE-b1 and DE-b2 that are spaced from each other, a cost to form the sub-dummy electrodes DE-b1 and DE-b2 may be reduced.

FIG. 12C is a plan view of a display module according to one or more embodiments of the present disclosure.

The display module may include a light blocking layer BML, a light blocking layer connection line BML-L, semiconductor pattern units SCP-U, scan lines SLi−1, SLi, and SLi+1, an emission control line ECLi, first gate electrodes G1, and a dummy electrode DE-c. In FIG. 12C, descriptions about the light blocking layer BML, the light blocking layer connection line BML-L, the semiconductor pattern units SCP-U, the scan lines SLi−1, SLi, and SLi+1, the emission control line ECLi, and the first gate electrodes G1 are substantially the same as those described with reference to FIGS. 10 to 11C, and thus, descriptions hereinafter will be focused on different features of the dummy electrode DE-c.

For the convenience explanation, in FIG. 12C, areas in which first, second, third-first, and third-second pixel circuits PC11, PC12, PC13a, and PC13b described with reference to FIG. 5 are disposed are indicated by a dotted-line quadrangular shape.

The dummy electrode DE-c may include a first portion PT1 and a second portion PT2.

The first portion PT1 of the dummy electrode DE-c may extend in the second direction DR2, and when viewed in the first direction DR1 from a transmission area BT (refer to FIG. 5) to a display area BA (refer to FIG. 5), the first portion PT1 may overlap at least one semiconductor pattern unit SCP-U. FIG. 12C shows the structure in which the first portion PT1 of the one dummy electrode DE-c overlaps two semiconductor pattern units SCP-U when viewed in the first direction DR1 from the transmission area BT (refer to FIG. 5) to the display area BA (refer to FIG. 5).

The second portion PT2 of the dummy electrode DE-c may extend in the first direction DR1 and may be connected to both ends of the first portion PT1. The number of the second portions PT2 included in one dummy electrode DE-c may be plural.

A light LE (refer to FIG. 8B) entering a second insulating layer 20 (refer to FIG. 8B) may not enter parallel to the first direction DR1, but may enter in a direction between the first direction DR1 and the second direction DR2.

In a case where the dummy electrode DE-c is provided in plural and the dummy electrodes DE-c are spaced from each other in the second direction DR2, the second portion PT2 of the dummy electrode DE-c may efficiently block the light LE (refer to FIG. 8B) that enters along the direction between the first direction DR1 and the second direction DR2 between the dummy electrodes DE-c that are spaced from each other in the second direction DR2.

Although the embodiments of the present disclosure have been described, it is understood that the present disclosure should not be limited to these embodiments but various changes and modifications can be made by one ordinary skilled in the art within the spirit and scope of the present disclosure as hereinafter claimed.

Therefore, the disclosed subject matter should not be limited to any single embodiment described herein, and the scope of the present disclosure shall be determined according to the attached claims and their equivalents.

What is claimed is:

1. A display panel comprising:
a base layer comprising a first area comprising a display area and a transmission area and a second area around at least a portion of the first area and having a light transmittance lower than the first area;
first pixels, each of the first pixels comprising sub-pixels and located in the display area; and
a dummy electrode in the display area,
wherein each of the sub-pixels in the first pixels comprises a pixel circuit comprising first transistors and a light emitting element connected to the first transistors, each of the first transistors comprising a semiconductor pattern unit and a gate electrode overlapping the semiconductor pattern unit, and the dummy electrode is spaced from the semiconductor pattern unit in a plan view.

2. The display panel of claim 1, further comprising:
a first insulating layer on which the gate electrode and the dummy electrode are located, the first insulating layer being on the base layer;
a second insulating layer on the first insulating layer and covering the gate electrode and the dummy electrode; and
a third insulating layer on the second insulating layer and covering the second insulating layer.

3. The display panel of claim 2, wherein the second insulating layer has a refractive index greater than a refractive index of the first insulating layer and a refractive index of the third insulating layer.

4. The display panel of claim 2, wherein the second insulating layer comprises silicon nitride (SiNx), and each of the first insulating layer and the third insulating layer comprises silicon oxide (SiOx).

5. The display panel of claim 1, wherein the dummy electrode extends in one direction and has a continuous shape in a plan view.

6. The display panel of claim 1, wherein the dummy electrode comprises a plurality of sub-dummy electrodes, the sub-dummy electrodes are spaced from each other, and the sub-dummy electrodes at least partially overlap each other when viewed in a direction from the transmission area to the pixel circuit.

7. The display panel of claim 1, wherein the dummy electrode comprises a first portion extending in a second direction and overlapping at least one semiconductor pattern when viewed in a first direction from the transmission area to the display area and second portions extending in the first direction and respectively connected to both ends of the first portion.

8. The display panel of claim 1, further comprising a light blocking layer on the base layer, wherein the light blocking layer overlaps the display area and does not overlap the transmission area, and the dummy electrode overlaps the light blocking layer.

9. The display panel of claim 1, further comprising:
a plurality of light blocking layers on the base layer; and
light blocking layer connection lines located between two light blocking layers of the plurality of light blocking layers and connecting the two light blocking layers to each other.

10. The display panel of claim 1, wherein the display area comprises a plurality of display areas, the first area further comprises a line area located between the display areas, and the transmission area is around the display area and the line area.

11. The display panel of claim 1, wherein the dummy electrode and the gate electrode comprise a same material.

12. The display panel of claim 1, further comprising second pixels, each of the second pixels comprising sub-pixels and located in the second area, wherein each of the sub-pixels in the second pixels comprises a pixel circuit comprising second transistors and a light emitting element connected to the second transistors, and the sub-pixels in the first pixels are greater than the sub-pixels in the second pixels, and configured to emit a same color light as the sub-pixels in the first pixels.

13. The display panel of claim 12, wherein each of the first pixels comprises one first sub-pixel configured to emit a first color light, one second sub-pixel configured to emit a second color light, and two third sub-pixels configured to emit a third color light, the first sub-pixel is spaced from the second sub-pixel in one direction, one third sub-pixel of the two third sub-pixels is spaced from an other third sub-pixel of the two third sub-pixels, the first sub-pixel is spaced from the one third sub-pixel in a first diagonal direction, the second sub-pixel is spaced from the one third sub-pixel in a second diagonal direction, and a light emitting area of each of the first, second, and third sub-pixels increases in an order of the third sub-pixels, the second sub-pixel, and the first sub-pixel.

14. The display panel of claim 1, wherein a density of the first pixels in the first area is less than a density of second pixels in the second area.

15. The display panel of claim 1, wherein the dummy electrode overlaps at least two semiconductor pattern units when viewed in a direction from the transmission area to the pixel circuit.

16. The display panel of claim 1, further comprising an electronic module overlapping the first area and located under the display panel, wherein the electronic module comprises at least one of a light emitting module and a light receiving module.

17. A display panel comprising:
a base layer comprising a first area comprising a display area and a transmission area and a second area around at least a portion of the first area and having a light transmittance lower than the first area;
first pixels, each of the first pixels comprising sub-pixels located in the display area; and
a dummy electrode in the display area;
wherein each of the sub-pixels comprises a pixel circuit comprising first transistors and a light emitting element connected to the first transistors, each of the first transistors comprises a semiconductor pattern unit and a gate electrode overlapping the semiconductor pattern unit, and at least a portion of the semiconductor pattern unit is blocked by the dummy electrode when viewed in a direction from the transmission area to the pixel circuit.

18. The display panel of claim 17, further comprising:
a first insulating layer on which the gate electrode and the dummy electrode are located, the first insulating layer being on the base layer;
a second insulating layer on the first insulating layer and covering the gate electrode and the dummy electrode; and
a third insulating layer on the second insulating layer and covering the second insulating layer, wherein the second insulating layer has a refractive index greater than a refractive index of the first insulating layer and a refractive index of the third insulating layer.

19. The display panel of claim 18, wherein the second insulating layer comprises at least one curved portion, and the curved portion overlaps at least a portion of the dummy electrode.

20. The display panel of claim 17, wherein a number of the semiconductor pattern units partially blocked by the dummy electrode is two or more when viewed in the direction from the transmission area to the pixel circuit.
